(19) United States
(12) Patent Application Publication
(10) Pub. No.: US 2011/0114600 A1
(43) Pub. Date: May 19, 2011

(54) PLASMA PROCESSING APPARATUS AND PLASMA PROCESSING METHOD

(75) Inventors: Masaki Hirayama, Sendai-shi (JP); Tadahiro Ohmi, Sendai-shi (JP)

(73) Assignees: TOKYO ELECTRON LIMITED, Tokyo (JP); TOHOKU UNIVERSITY, Sendai-shi (JP)

(21) Appl. No.: 12/997,183

(22) PCT Filed: Jun. 3, 2009
(86) PCT No.: PCT/JP2009/060128

§ 371 Date: Jan. 28, 2011

(30) Foreign Application Priority Data
Jun. 11, 2008 (JP) 2008-152915
Jun. 11, 2008 (JP) 2008-153431

(51) Int. Cl. C23F 1/08; C23C 16/50; C23C 16/455; C23F 1/00

(52) U.S. Cl. 216/67; 118/723 R; 427/569; 156/345.1; 118/723 E; 156/345.43

(57) ABSTRACT

Provided is a coaxial waveguide distributor including a coaxial waveguide which extends non-perpendicularly at a branched portion. A plasma processing apparatus in which a gas is excited by microwaves to plasma process an object to be processed includes a processing container, a microwave source which outputs microwaves, a transmission line which transmits the microwaves output from the microwave source, a plurality of dielectric plates which are provided on an inner wall of the processing container and emit microwaves into the processing container, a plurality of first coaxial waveguides which are adjacent to the plurality of dielectric plates and transmit microwaves to the plurality of dielectric plates, and one stage or two or more stages of a coaxial waveguide distributor which distributes and transmits the microwaves transmitted through the transmission line to the plurality of first coaxial waveguides. The coaxial waveguide distributor include s a second coaxial waveguide having an input portion and three or more of third coaxial waveguides which are connected to the second coaxial waveguide. Each of the third coaxial waveguides extends non-perpendicularly with respect to the second cable.

### TECHNICAL FIELD

The present invention relates to a plasma processing apparatus and a plasma processing method for generating plasma by using electromagnetic waves and plasma processing an object to be processed, and more particularly, to impedance matching at a transmission line.

### BACKGROUND ART

As glass substrates for flat panel displays or solar cells have become larger in recent years, a substrate larger than 3 m square has already been used. In order to manufacture flat panel displays or solar cells, plasma processing apparatuses for generating uniform and stable plasma over a wide area exceeding a substrate size are necessary. Also, since plasma processing has been diversified as products have higher performance and more functions, apparatuses capable of satisfying a wide range of processing conditions are required. As apparatuses which are most likely to meet such requirements, there are microwave plasma apparatuses.

If plasma is excited by the energy of microwaves, since a frequency is high, plasma of low electron temperature is obtained. If electron temperature is low, since the energy of ions incident on a surface of a substrate or an inner surface of a chamber is kept at a low level, processing without damage due to ion irradiation or without contamination due to impurities can be performed. Also, since the excessive dissociation of a material gas is suppressed and thus desired radicals or ions can be generated, high quality and high speed processing can be performed.

Meanwhile, since wavelengths of microwaves are short in terms of a substrate size, it is difficult to excite uniform plasma on a substrate having a large size. Also, since cutoff density (which is proportional to the square of a frequency) is high, it is difficult to satisfy a wide range of processing conditions. Accordingly, the inventor has suggested a cell division method in which a plasma excitation frequency is low, and a plasma excitation area is divided into cells and microwave power is uniformly supplied to the cells, thereby making it possible to excite uniform and stable plasma over a wide area under a wide range of conditions (refer to, for example, Patent Document 1).

[Patent document 1] Japanese Laid-Open Patent Publication No. 2006-310794

### DISCLOSURE OF THE INVENTION

### Technical Problem

In the cell division method, microwave power generated by a few, that is, one or two, microwave sources, is uniformly distributed and supplied to a plurality of cells, e.g., 100 cells at the maximum. To this end, multiple stages of distributors for transmitting microwaves having the same amplitude and the same phase to all cells are necessary.

In a large apparatus, very large microwave power should be dealt with. For example, a power density of about 2 W/cm² is needed to excite stable microwave plasma, and thus a power of 200 kW is needed in an apparatus for 10^{th}-generation glass substrates (with a dimension of 2880×3080 mm). In particular, if reflection from plasma or reflection in a distributor is large, loss in a transmission line or a matcher is increased. In addition, since large standing waves are generated in the transmission line, an electric discharge may occur or temperature may be partially abnormally increased in the transmission line, which is very dangerous. Accordingly, a coaxial waveguide distributor for transmitting microwaves of large power by always matching impedance to plasma as a load and performing branching is necessary.

A distributor is disposed on an entire surface of a lid over an apparatus. Also, in the lid, a plurality of refrigerant passages through which a refrigerant for maintaining the lid at a constant temperature, gas passages through which a gas is supplied to a shower plate formed on a surface of the lid at the substrate side, and the like are formed. Since the distributor must be formed at a position not interfering with them, the distributor needs to have a simple and compact structure.

There is a method of performing multi-branching by connecting a plurality of 2-branch structures in a tournament manner. However, if the number of branches is large, since a complex three-dimensional circuit is obtained, it is difficult to mount the complex three-dimensional circuit on the lid. Also, there is a method in which branching is performed by connecting a plurality of coaxial waveguides to one coaxial waveguide at regular pitches. However, if coaxial waveguides having the same characteristic impedance are simply connected, large reflection occurs, thereby failing to transmit microwaves of large power.

In general, when a plasma excitation area is about 60 to 80 mm larger than a substrate size, uniform plasma processing can be performed. However, if terminal coaxial waveguides are vertically connected to a distributor at regular intervals, pitches of the terminal coaxial waveguides need to be equal to integer multiples of π rad in order to transmit microwaves having the same amplitude and the same phase to respective cells. In this case, since a cell size is restricted by guide wavelengths of the microwaves, the cell size cannot be determined in accordance with the substrate size. Also, a distribution number for constituting a useful distributor is limited. For example, while it is easy to constitute a distributor with 2^{m} (m is an integer), it may be difficult to constitute a useful distributor with another distribution number. Accordingly, the apparatus becomes too large. Also, since the plasma excitation area becomes too large, in order to maintain plasma, more power than needed for processing is consumed. Since in a large apparatus, very large microwave power should be deal with, to have an appropriate plasma excitation area in accordance with a substrate size leads to a great reduction in the amount of power, thereby reducing costs and effectively using resources.

Accordingly, considering the aforesaid problems, there is provided a plasma processing apparatus for adjusting an impedance in a multi-branched portion.

Also, there is provided a plasma processing apparatus having a coaxial waveguide distributor including coaxial waveguides that extend non-perpendicularly in branched portions.

### Technical Solution

In order to solve the problems, according to an embodiment of the present invention, there is a plasma processing apparatus for plasma processing an object to be processed by exciting a gas by using electromagnetic waves, the plasma processing apparatus including: a processing container; an electromagnetic wave source which outputs electromagnetic waves; a transmission line which transmits the electromagnetic waves output from the electromagnetic wave source; a plurality of dielectric plates which are disposed on an inner wall of the processing container and emit electromagnetic waves into the processing container; a plurality of first coaxial waveguides which are adjacent to the plurality of dielectric plates and transmit electromagnetic waves to the plurality of dielectric plates; and one stage or two or more stages of a coaxial waveguide distributor which distributes and transmits the electromagnetic waves transmitted through the transmission line to the plurality of first coaxial waveguides, wherein at least one stage of the coaxial waveguide distributor includes a second coaxial waveguide having an input portion and 3 or more of third coaxial waveguides connected to the second coaxial waveguide, wherein each of the third coaxial waveguides has a portion that extends non-perpendicularly with respect to the second coaxial waveguide.

Accordingly, at least one stage of the coaxial waveguide distributor includes a second coaxial waveguide and 3 or more of the third coaxial waveguides, and each of the third coaxial waveguides extends non-perpendicularly with respect to the second coaxial waveguide. Accordingly, since a plasma excitation area can be determined in accordance with a substrate size without being restricted by guide wavelengths, power consumption can be reduced. Also, the entire apparatus can be prevented from being increased too much. As for shapes of the third coaxial waveguides, the third coaxial waveguides having curved shapes may be connected to the second coaxial waveguide or the third coaxial waveguides having bar shapes may be obliquely connected to the second coaxial waveguide.

Each of the third coaxial waveguides may have an impedance transformation mechanism. Accordingly, since the second coaxial waveguide can be multi-branched to the third coaxial waveguides while an impedance is matched to plasma as a load, microwaves of large power can be transmitted.

The number of connected portions between the second coaxial waveguide and the third coaxial waveguides in a space between the input portion of the second coaxial waveguide and an end portion of the second coaxial waveguide may be 2 or less. This is because although the frequency of electromagnetic waves is changed, the balance of power supplied to the third coaxial waveguides is hard to be broken.

From among connected portions between the second coaxial waveguide and the third coaxial waveguides, an electrical length between connected portions without the input portion therebetween may be substantially equal to an integer multiple of π rad. Accordingly, power can be equally distributed from the second coaxial waveguide to the third coaxial waveguides. Also, when an electrical length between the connected portions is substantially an integer multiple of 2π rad, not only desired amplitude but also desired phase can be achieved.

In each of connected portions between the second coaxial waveguide and the third coaxial waveguides, 2 of the third coaxial waveguides may be connected to the second coaxial waveguide. As a result, since the number of connected portions is reduced, although the frequency of electromagnetic waves is changed, the balance of power supplied to the third coaxial waveguides can be hard to be broken.

An inner conductor of each of the third coaxial waveguides may be narrower than an inner conductor of the second coaxial waveguide, and an outer conductor of each of the third coaxial waveguides may be narrower than an outer conductor of the second coaxial waveguide, in order to reduce the disturbance of a transmission state of electromagnetic waves transmitted to the coaxial waveguides.

An inner conductor and an outer conductor of the second coaxial waveguide may be short-circuited at at least one end portion of the second coaxial waveguide, wherein an electrical length in a space between the end portion of the second coaxial waveguide and a connected portion closest to the end portion among connected portions between the second coaxial waveguide and the third coaxial waveguides is substantially equal to an odd multiple of π/2 rad. Accordingly, in the transmission of electromagnetic waves, since there seems no portion between the end portion of the second coaxial waveguide and the connected portion, a transmission line can be easily designed.

When an impedance obtained by observing a plasma side from each of the first coaxial waveguides is matched, an impedance obtained by observing the third coaxial waveguide side from a connected portion between the second coaxial waveguide and each of the third coaxial waveguides may be substantially resistive, wherein, when a resistance obtained by observing the third coaxial waveguide side from the connected portion is Rᵣ₃, the number of the third coaxial waveguides connected to a space between the input portion of the second coaxial waveguide and one end of the second coaxial waveguide is Nₛ, and a characteristic impedance of the second coaxial waveguide is Z_{c2}, the characteristic impedance Z_{c2} of the second coaxial waveguide is substantially equal to Rᵣ₃/Nₛ. As a result, since there is no reflection when observing from a distributor input side, microwaves of large power can be transmitted.

When a fourth coaxial waveguide having a characteristic impedance Z_{c4} is connected to the input portion of the second coaxial waveguide and an impedance obtained by observing a plasma side from each of the first coaxial waveguides is matched, an impedance obtained by observing the third coaxial waveguide side from a connected portion between the second coaxial waveguide and each of the third coaxial waveguides may be substantially resistive, wherein, when a resistance obtained by observing the third coaxial waveguide side from the connected portion is Rᵣ₃ and the number of the third coaxial waveguides connected to the second coaxial waveguide is Nₜ, the characteristic impedance Z_{c4} is substantially equal to Rᵣ₃/Nₜ. As a result, since there is no reflection when observing from a distributor input side, microwaves of large power can be transmitted.

An electrical length of each of the third coaxial waveguides may be substantially π/2 rad. As a result, an impedance obtained by observing the third coaxial waveguide side from a connected portion between the second coaxial waveguide and each of the third coaxial waveguides can be substantially resistive.

In an inner conductor of each of the third coaxial waveguides, a portion connected with the second coaxial waveguide may be narrower than other portions. An electrical length of the third coaxial waveguides can be adjusted by adjusting a thickness or a length of the narrowed portion.

When an impedance obtained by observing a plasma side from each of the first coaxial waveguides is matched, an impedance obtained by observing an output side from an output end of each of the third coaxial waveguides is substantially resistive, and when a resistance obtained by observing the output side from the output end of each of the third coaxial waveguides is Rᵣ₅, the number of the third coaxial waveguides connected to a space between the input portion of the second coaxial waveguide and one end of the second coaxial waveguide is Nₛ, and a characteristic impedance of the second coaxial waveguide is Z_{c2}, a characteristic impedance Z_{c3} of each of the third coaxial waveguides may be substantially equal to (Rᵣ₅×Nₛ×Z_{c2})^{1/2}. As a result, since there is no reflection when observing from an input side of the coaxial waveguide distributor, microwaves of large power can be transmitted.

When a fourth coaxial waveguide having a characteristic impedance Z_{c4} is connected to the input portion of the second coaxial waveguide and an impedance obtained by observing a plasma side from each of the first coaxial waveguides is matched, an impedance obtained by observing an output side from an output end of each of the third coaxial waveguides is substantially resistive, and when a resistance obtained by observing the output side from the output end of each of the third coaxial waveguides is Rᵣ₅, and the number of the third coaxial waveguides connected to the second coaxial waveguide is Nₜ, a characteristic impedance Z_{c3} of each of the third coaxial waveguides may be substantially equal to (R^{r5}×Nₜ×Z_{c4})^{1/2}. As a result, since there is no reflection when observing from an input side of the coaxial waveguide distributor, microwaves of large power can be transmitted.

An end of the third coaxial waveguide is connected to a fifth coaxial waveguide to form T-branched shape. In at least one of an inner conductor of each of the third coaxial waveguides and an inner conductor of the fifth coaxial waveguide, the T-branched connected portion may be narrower than other portions. In at least one of an outer conductor of each of the third coaxial waveguides and an outer conductor of the fifth coaxial waveguide, the T-shaped connected portions may be thicker than other portions

If a narrowed portion or a thickened portion is formed in the third coaxial waveguides, an electrical length of the third coaxial waveguides can be adjusted by adjusting a length or a thickness of the narrowed portion or the thickened portion. In the case of the fifth coaxial waveguide, an electrical length of the fifth coaxial waveguide can be adjusted by adjusting a length or a thickness of the fifth coaxial waveguide. Also, in general, characteristic impedances of the third coaxial waveguides and the fifth coaxial waveguide are greatly different from each other. Regarding a branched portion, unnecessary reflection in the branched portion can be suppressed by forming a buffer portion by narrowing an inner conductor of the fifth coaxial waveguide.

If the T-branched connected portion in the inner conductor of the fifth coaxial waveguide is narrowed, in the narrowed portion of the inner conductor of the fifth coaxial waveguide, a length between the T-branched connected portion and the end of one branch is different from a length between the T-branched connected portion and the end of another branch. Accordingly, a ratio of power of microwaves supplied to the ends of the two branches of the T-branch can be adjusted.

The plasma processing apparatus may further include a plurality of metal electrodes which are electrically connected to the inner wall of the processing container and are adjacent in a one-to-one correspondence manner to the plurality of dielectric plates, wherein each of the dielectric plates is exposed from a space between each of the adjacent metal electrodes and the inner wall of the processing container on which each of the dielectric plates is not disposed, wherein, each of the dielectric plates and either the inner wall of the processing container on which each of the dielectric plates is not disposed or metal covers disposed on the inner wall have substantially similar shapes or substantially symmetric shapes. Accordingly, power of electromagnetic waves can be substantially equally supplied to both sides from the dielectric plates.

In order to solve the problems, according to another embodiment of the present invention, there is provided a plasma processing apparatus for plasma processing an object to be processed by exciting a gas by using electromagnetic waves, the plasma processing apparatus including: a processing container; an electromagnetic wave source which outputs electromagnetic waves; a transmission line which transmits the electromagnetic waves output from the electromagnetic wave source; a plurality of dielectric plates which are disposed on an inner wall of the processing container and emit electromagnetic waves into the processing container; a plurality of first coaxial waveguides which are adjacent to the plurality of dielectric plates and transmit electromagnetic waves to the plurality of dielectric plates; and one stage or two or more stages of a coaxial waveguide distributor which distributes and transmits the electromagnetic waves transmitted through the transmission line to the plurality of first coaxial waveguides, wherein, in at least one stage of the coaxial waveguide distributor, a characteristic impedance of a coaxial waveguide at an input side and a characteristic impedance of a coaxial waveguide at an output side are different from each other.

Accordingly, in at least one end of the coaxial waveguide distributor, impedance matching can be achieved at a connected portion between a coaxial waveguide at an input side and a coaxial waveguide at an output side by changing a characteristic impedance of the coaxial waveguide at the input side and the coaxial waveguide at the output side. For example, the coaxial waveguide at the input side is connected to the coaxial waveguide at the output side to form a 2-branched shape, wherein, in the 2-branched portion, a characteristic impedance of the coaxial waveguide at the output side is substantially two times higher than a characteristic impedance of the coaxial waveguide at the input side. Accordingly, microwaves of large power can be transmitted.

In an outer conductor of the coaxial waveguide at the output side constituting the 2-branched portion, the connected portion may be thicker than other portions. Reflection in a branched portion can be reduced by suppressing an electrostatic capacity between an inner conductor and an outer conductor in the branched portion to a low level.

In order to solve the problems, according to another embodiment of the present invention, there is provided a plasma processing method including: introducing a gas into a processing container; outputting electromagnetic waves from an electromagnetic wave source; transmitting the output electromagnetic waves to a transmission line; distributing and transmitting the electromagnetic waves transmitted through the transmission line to a plurality of first coaxial waveguides from one stage or two or more stages of a coaxial waveguide distributor; and emitting the electromagnetic waves transmitted through the first coaxial waveguides into the processing container from a plurality of dielectric plates that are disposed on an inner wall of the processing container, wherein, when the electromagnetic waves are transmitted to the coaxial waveguide distributor, at least one stage of the coaxial waveguide distributor includes a second coaxial waveguide having an input portion and 3 or more of third coaxial waveguides connected to the second coaxial waveguide, the electromagnetic waves are transmitted to the third coaxial waveguides each having a portion that extends non-perpendicularly with respect to the second coaxial waveguide, and the gas is excited by the electromagnetic waves emitted into the processing container through the first coaxial waveguides to plasma-process an object to be processed.

Accordingly, in at least one stage of the coaxial waveguide distributor, the second coaxial waveguide is multi-branched to 3 or more of the third coaxial waveguides connected non-perpendicularly to the second coaxial waveguide. Accordingly, microwaves can be equally distributed to a plurality of cells which are determined in accordance with a substrate size. As a result, since the entire apparatus is not increased too much and thus a plasma excitation area is not also increased too much, power consumption can be reduced.

In order to solve the problems, according to another embodiment of the present invention, there is provided a plasma processing method including: introducing a gas into a processing container; outputting electromagnetic waves from an electromagnetic wave source; transmitting the output electromagnetic waves to a transmission line; distributing and transmitting the transmitted electromagnetic waves to a plurality of first coaxial waveguides from a coaxial waveguide distributor that is formed by one stage or two or more stages of coaxial waveguides, wherein, in at least one stage, a characteristic impedance of a coaxial waveguide at an input side and a characteristic impedance of a coaxial waveguide at an output side are different from each other; transmitting the electromagnetic waves to a plurality of dielectric plates that are adjacent to the plurality of first coaxial waveguides and are disposed on an inner wall of the processing container; emitting the electromagnetic waves from the plurality of dielectric plates into the processing container; and exciting a gas by using the emitted electromagnetic waves to plasma process an object to be processed in the processing container.

Accordingly, an impedance in a branched portion transmitted when, for example, microwaves are distributed and transmitted can be matched by changing a characteristic impedance of a coaxial waveguide at an input side and a coaxial waveguide at an output side of the coaxial waveguide distributor.

Also, in order to solve the problems, according to another embodiment of the present invention, there is provided a plasma processing apparatus for plasma processing an object to be processed by exciting a gas by using electromagnetic waves, the plasma processing apparatus including: a processing container; an electromagnetic wave source which outputs electromagnetic waves; a transmission line which transmits the electromagnetic waves output from the electromagnetic wave source; a plurality of dielectric plates which are disposed on an inner wall of the processing container and emit the electromagnetic waves into the processing container; a plurality of first coaxial waveguides which are adjacent to the plurality of dielectric plates and transmit the electromagnetic waves to the plurality of dielectric plates; and one state or two or more stages of a coaxial waveguide distributor which distributes and transmits the electromagnetic waves transmitted through the transmission line to the plurality of first coaxial waveguides, wherein at least one stage of the coaxial waveguide distributor includes a second coaxial waveguide having an input portion and 3 or more of third coaxial waveguides substantially perpendicularly connected to the second coaxial waveguide, wherein each of the third coaxial waveguides has an impedance transformation mechanism.

Accordingly, in at least one stage of the coaxial waveguide distributor, the second coaxial waveguide is multi-branched to 3 or more of the third coaxial waveguides connected substantially perpendicularly to the second coaxial waveguide. The third coaxial waveguides have a mechanism for adjusting a characteristic impedance, and thus can match an impedance in such a manner that there is almost no reflection when observing from a plasma side from an output side of the third coaxial waveguides. As a result, microwaves of large power can be transmitted.

The number of connected portions between the second coaxial waveguide and the third coaxial waveguides in a space between the input portion of the second coaxial waveguide and an end portion of the second coaxial waveguide may be 2 or less. This is because although the frequency of electromagnetic waves is changed, the balance of power supplied to the third coaxial waveguides is hard to be broken.

When guide wavelength of the second coaxial waveguide is λg₂, a length between connected portions between the second coaxial waveguide and the third coaxial waveguides may be substantially equal to an integer multiple of λg₂/2. Accordingly, power can be uniformly distributed from the second coaxial waveguide to the third coaxial waveguides. Also, when guide wavelengths of the second coaxial waveguide are λg₂, a length between connected portions between the second coaxial waveguide and the third coaxial waveguides may be substantially equal to an integer multiple of λg₂ and desired amplitude and phase can be achieved. Also, in case that a length between connected portions when guide wavelength of a coaxial waveguide is λg is substantially λAg/2, an electrical length between the connected portions may be expressed as π rad.

2 of the third coaxial waveguides may be connected to the second coaxial waveguide at a connected portion between the second coaxial waveguide and each of the third coaxial waveguides. As a result, the balance of power supplied to the third coaxial waveguides can be hard to be broken by reducing the number of the connected portions although the frequency of electromagnetic waves is changed.

An inner conductor of each of the third coaxial waveguides may be narrower than an inner conductor of the second coaxial waveguide, and an outer conductor of each of the third coaxial waveguides may be narrower than an outer conductor of the second coaxial waveguide, in order to reduce the disturbance of a transmission state of electromagnetic waves transmitted through the second coaxial waveguide.

An inner conductor and an outer conductor of the second coaxial waveguide may be short-circuited at at least one end portion of the second coaxial waveguide, wherein an electrical length in a space between the end portion of the second coaxial waveguide and a connected portion closest to the end portion among connected portions between the second coaxial waveguide and the third coaxial waveguides is substantially equal to an odd multiple of π/2 rad. Accordingly, in the transmission of electromagnetic waves, since there seems no portion between the end portion of the second coaxial waveguide and the connected portion, a transmission line can be easily designed.

When an impedance obtained by observing a plasma side from each of the first coaxial waveguides is matched, an impedance obtained by observing the third coaxial waveguide side from a connected portion between the second coaxial waveguide and each of the third coaxial waveguides may be substantially resistive, wherein, when a resistance obtained by observing the third coaxial waveguide side from the connected portion is Rᵣ₃, the number of the third coaxial waveguides connected to a space between the input portion of the second coaxial waveguide and one end of the second coaxial waveguide is Nₛ, and a characteristic impedance of the second coaxial waveguide is Z_{c2}, the characteristic impedance Z_{c2} of the second coaxial waveguide is substantially equal to Rᵣ₃/Nₛ. As a result, since there is no reflection when observing from an input side of the distributor, microwaves of large power can be transmitted.

A fourth coaxial waveguide having a characteristic impedance Z_{c4} may be connected to the input portion of the second coaxial waveguide, wherein, when an impedance obtained by observing a plasma side from each of the first coaxial waveguides is matched, an impedance obtained by observing the third coaxial waveguide side from a connected portion between the second coaxial waveguide and each of the third coaxial waveguides is substantially resistive, wherein, when a resistance obtained by observing the third coaxial side from the connected portion is Rᵣ₃ and the number of the third coaxial waveguides connected to the second coaxial waveguide is Nₜ, the characteristic impedance Z_{c4} is substantially equal to Rᵣ₃/Nₜ. As a result, since there is no reflection when observing from an input side of the distributor, microwaves of large power can be transmitted.

An electrical length of each of the third coaxial waveguides may be substantially π/2 rad. As a result, an impedance obtained by observing each of the third coaxial waveguides from a connected portion between the second coaxial waveguide and each of the third coaxial waveguides can be substantially resistive.

In an inner conductor of each of the third coaxial waveguides, a portion connected with the second coaxial waveguide may be narrower than other portions. An electrical length of each of the third coaxial waveguides can be adjusted by adjusting a thickness or a length of the narrowed portion.

When an impedance obtained by observing a plasma side from each of the first coaxial sides is matched, an impedance obtained by observing an output side from an output end of each of the third coaxial waveguides is substantially resistive, and when a resistance obtained by observing the output side from the output end of each of the third coaxial waveguides is Rᵣ₅, the number of the third coaxial waveguides connected to a space between the input portion of the second coaxial waveguide and one end of the second coaxial waveguide is Nₛ, and a characteristic impedance of the second coaxial waveguide is Z_{c2}, a characteristic impedance of each of the third coaxial waveguides may be substantially equal to (Rᵣ₅×Nₛ×Z_{c2})^{1/2}. As a result, since there is no reflection when observing from an input side of the coaxial waveguide distributor, microwaves of large power can be transmitted.

A fourth coaxial waveguide having a characteristic impedance Z_{c4} may be connected to the input portion of the second coaxial waveguide, wherein, when an impedance obtained by observing a plasma side from each of the first coaxial waveguides is matched, an impedance obtained by observing an output side from an output end of each of the third coaxial waveguides is substantially resistive, and when a resistance obtained by observing the output side from the output side of each of the third coaxial waveguides is Rᵣ₅ and the number of the third coaxial waveguides connected to the second coaxial waveguide is Nₜ, a characteristic impedance of each of the third coaxial waveguides is substantially equal to (R^{r5×N}ₜ×Z_{c4})^{1/2}. As a result, since there is no reflection when observing from an input side of the coaxial waveguide distributor, microwaves of large power can be transmitted.

An impedance transformation mechanism of each of the third coaxial waveguides may be a dielectric member disposed in a connected portion between an inner conductor of the second coaxial waveguide and an inner conductor of each of the third coaxial waveguides.

When the number of the third coaxial waveguides connected to a space between the input portion of the second coaxial waveguide and one end of the second coaxial waveguide is Nₛ, a characteristic impedance of the second coaxial waveguide is Z_{c2}, and a characteristic impedance of each of the third coaxial waveguides is Z_{c3}, a relationship Z_{c3}<Nₛ×Z_{c2} may be satisfied, wherein a reactance Xᵣ of the dielectric member is substantially equal to −(Z_{c3}(Nₛ×Z_{c2}−Z_{c3}))^{1/2}, wherein, in at least one end portion of the second coaxial waveguide, a reactance Xₚ obtained by observing the end portion side of the second coaxial waveguide from a connected portion closest to the end portion among connected portions between the second coaxial waveguide and the third coaxial waveguides is substantially equal to −Xᵣ×Z_{c2}/(Nₛ×Z_{c2}−Z_{c3}).

A fourth coaxial waveguide having a characteristic impedance Z_{c4} may be connected to the input portion of the second coaxial waveguide, wherein, when the number of the third coaxial waveguides connected to the second coaxial waveguide is Nₜ and a characteristic impedance of each of the third coaxial waveguides is Z_{c3}, a relationship Z₃<Nₜ×Z_{c4} is satisfied, wherein a reactance Xᵣ of the dielectric member is substantially equal to −(Z_{c3}(Nₜ×Z_{c4}−Z_{c3}))^{1/2}, wherein, at both ends of the second coaxial waveguide, a reactance Xₚ obtained by observing the end portion side of the second coaxial waveguide from a connected portion closest to the end portion among connected portions between the second coaxial waveguide and the third coaxial waveguides is substantially equal to −2Xᵣ×Z_{c4}/(Nₜ×Z_{c4}−Z_{c3}).

An inner conductor and an outer conductor of the second coaxial waveguide may be short-circuited at at least one end of the second coaxial waveguide, and in such a manner that a reactance obtained by observing the end portion side from a connected portion closest to the end portion among connected portions between the second coaxial waveguide and the third coaxial waveguides is a desired value, a distance between the end portion and the connected portion closest to the end portion may be determined.

A dielectric ring may be disposed between an outer conductor and an inner conductor of the second coaxial waveguide.

A cross-sectional shape of an outer conductor of the second coaxial waveguide may be a non-circular shape. A cross-sectional shape of an outer conductor of the second coaxial waveguide may be a half-cylindrical shape with a base upward.

The plasma processing apparatus may include a plurality of metal electrodes which are electrically connected to the inner wall of the processing container and are adjacent in a one-to-one correspondence manner to the plurality of dielectric plates, wherein each of the dielectric plates is exposed from a space between each of the adjacent metal electrodes and the inner wall of the processing container on which each of the dielectric plates is not disposed, wherein, each of the dielectric plates and either the inner wall of the processing container on which each of the dielectric plates is not disposed or metal covers disposed on the inner wall have substantially similar shapes or substantially symmetric shapes.

In order to solve the problems, according to another embodiment of the present invention, there is provided a plasma processing method including: introducing a gas into a processing container; outputting electromagnetic waves from an electromagnetic wave source; transmitting the output electromagnetic waves to a transmission line; distributing and transmitting the electromagnetic waves transmitted through the transmission line to a plurality of first coaxial waveguides from one stage or two or more stages of a coaxial waveguide distributor; and emitting the electromagnetic waves transmitted through the first coaxial waveguides into the processing container from a plurality of dielectric plates that are disposed on an inner wall of the processing container, wherein, when the electromagnetic waves are transmitted to the coaxial waveguide distributor, at least one stage of the coaxial waveguide distributor includes a second coaxial waveguide having an input portion and 3 or more of third coaxial waveguides connected to the second coaxial waveguide, the electromagnetic waves are transmitted to the third coaxial waveguides each having an impedance transformation mechanism, and the gas is excited by the electromagnetic waves by using the electromagnetic waves emitted into the processing container through the first coaxial waveguides to plasma process an object to be processed.

Accordingly, in at least one stage of the coaxial waveguide distributor, the second coaxial waveguide is multi-branched to 3 or more of the third coaxial waveguides, and a characteristic impedance of the third coaxial waveguides is adjusted. Accordingly, an impedance can be matched in such a manner that there is almost no reflection when a plasma side is observed from an output side of each of the third coaxial waveguides. As a result, microwaves of large power can be transmitted.

### Advantageous Effects

As described above, according to the present invention, microwaves of large power can be efficiently transmitted by adjusting an impedance in multi-branched portions.

Also, according to the present invention, a plasma excitation area can be determined in accordance with a substrate size without being restricted by guide wavelength by using a coaxial waveguide distributor including coaxial waveguides that extend non-perpendicularly at branched portions.

### BRIEF DESCRIPTION OF THE DRAWINGS

FIG. 1 is a view (cross-sectional view taken along line 2-2 of FIG. 2) showing a ceiling surface of a microwave plasma processing apparatus according to a first embodiment.

FIG. 2 is a cross-sectional view taken along line 1-0-0′-1 of FIG. 1.

FIG. 3 is an enlarged view of a region Ex of FIG. 1.

FIG. 4 is a view showing a branch circuit according to the same embodiment.

FIG. 5 is a cross-sectional view taken along line 3-3 of FIG. 2.

FIG. 6 is a cross-sectional view taken along line 4-4 of FIG. 5.

FIG. 7 is a view for explaining a function of an impedance transformation unit.

FIG. 8 is a view showing a branch circuit according to a second embodiment.

FIG. 9 is a view showing a cut surface of a lid according to the same embodiment.

FIG. 10 is a view showing a branch circuit according to a third embodiment.

FIG. 11 is a view schematically showing a waveguide branch structure and a coaxial waveguide multi-branch structure according to the same embodiment.

FIG. 12 is a view showing a coaxial waveguide distributor according to a modified example.

FIG. 13 is a longitudinal-sectional view of the microwave plasma processing apparatus according to a fourth embodiment.

FIG. 14 is a cross-sectional view taken along line 6-6 of FIG. 13.

FIG. 15 is a cross-sectional view taken along line 7-7 of FIG. 13.

FIG. 16 is a view showing a ceiling surface of the microwave plasma processing apparatus according to a fifth embodiment.

FIG. 17 is a view for explaining a principle of impedance matching of a coaxial waveguide branch structure.

FIG. 18 is a view showing an impedance transformation-type branch circuit according to the same embodiment.

FIG. 19 is a cross-sectional view showing the cut lid according to the same embodiment.

FIG. 20 is a view showing a cut surface of a capacitively coupled-type lid according to the same embodiment.

FIG. 21 is a view showing a branch circuit according to a sixth embodiment.

FIG. 22 is a view showing a cut surface of the lid according to the same embodiment.

FIG. 23 is a view partially showing a cut surface of the lid according to a modified example of the sixth embodiment.

FIG. 24 is a view showing a branch circuit according to a seventh embodiment.

FIG. 25 is a view schematically showing a waveguide branch structure and a coaxial waveguide multi-branch structure according to the same embodiment.

### BEST MODE FOR CARRYING OUT THE INVENTION

Hereinafter, the present invention will be described in detail by explaining exemplary embodiments of the present invention with reference to the attached drawings. Also, like reference numerals in the drawings denote like elements, and repeated descriptions will be omitted.

### Embodiment 1

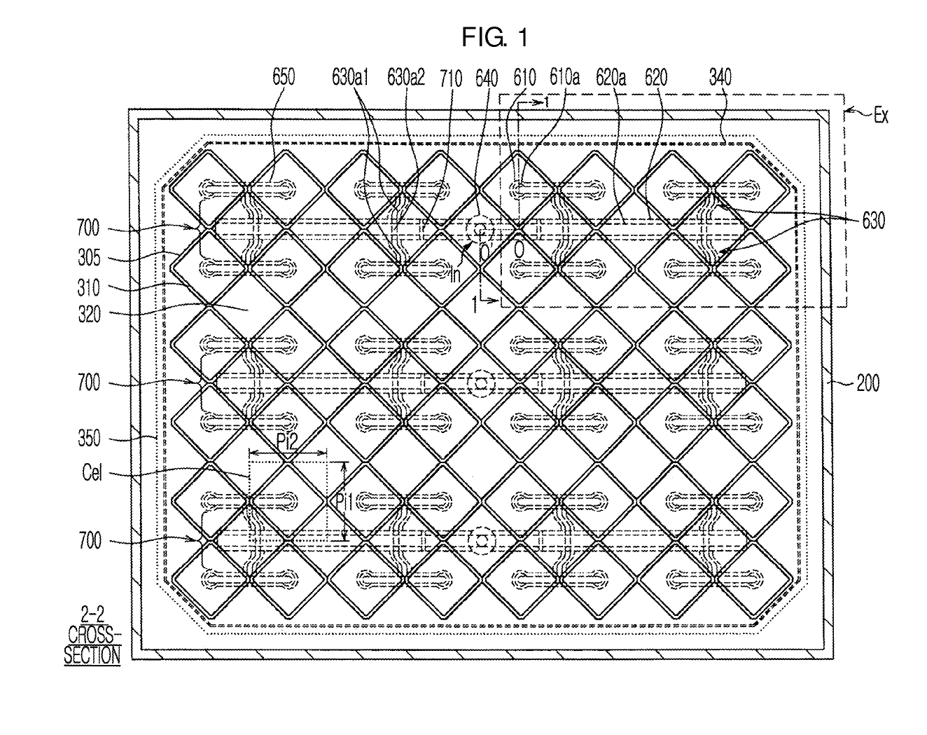

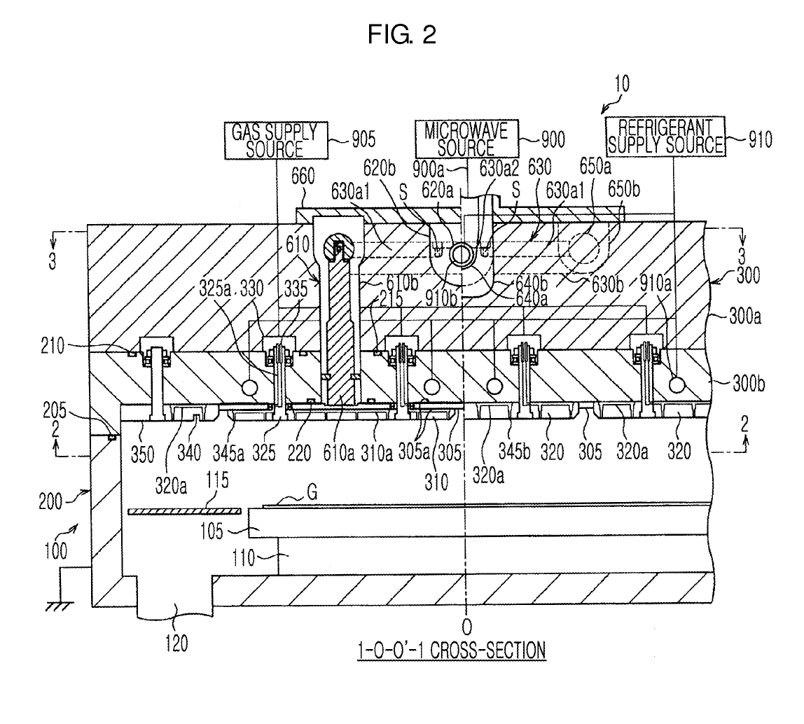

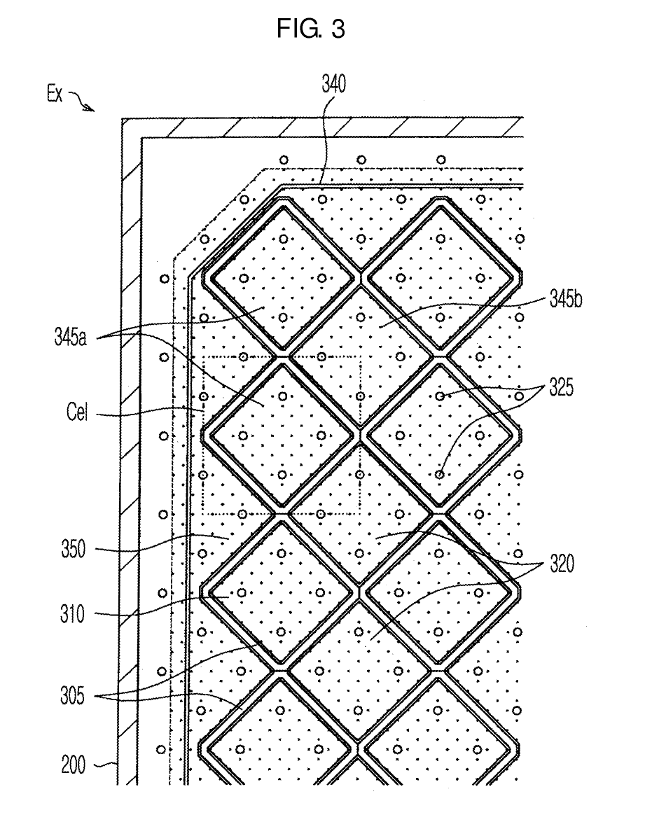

First, an outline of a microwave plasma processing apparatus according to a first embodiment of the present invention will be explained with reference to FIGS. 1 through 3. FIG. 1 shows a ceiling surface of the microwave plasma processing apparatus according to the present embodiment. FIG. 1 is a cross-sectional view taken along line 2-2 of FIG. 2. FIG. 2 shows a part of a longitudinal-sectional view of the microwave plasma processing apparatus 10. FIG. 2 is a cross-sectional view taken along line 1-0-0′-1 of FIG. 1. FIG. 3 is an enlarged view showing a region Ex of FIG. 1.

### (Outline of Microwave Plasma Processing Apparatus)

As shown in FIG. 2, the microwave plasma processing apparatus 10 includes a processing container 100 for plasma processing a glass substrate (hereinafter, referred to as a substrate G). The processing container 100 includes a container body 200 and a lid 300. The container body 200 has a cubic shape having an opened top and a closed bottom wherein the opened top is closed by the lid 300. The lid 300 includes an upper lid 300a and a lower lid 300b. An O-ring 205 is disposed on a contact surface between the container body 200 and the lower lid 300b. Accordingly, the container body 200 and the lower lid 300b are sealed to define a processing chamber. An O-ring 210 and an O-ring 215 are also disposed on a contact surface between the upper lid 300a and the lower lid 300b. Accordingly, the upper lid 300a and the lower lid 300b are sealed. The container body 200 and the lid 300 are formed of a metal, for example, an aluminum alloy or the like, and are electrically grounded.

A susceptor 105 (stage) on which the substrate G is held is provided inside the processing container 100. The susceptor 105 is formed of, for example, aluminum nitride. The susceptor 105 is supported by a supporter 110, and a baffle plate 115 for controlling the flow of a gas in the processing chamber in a desired state is provided around the susceptor 105. Also, a gas exhaust pipe 120 is provided at a bottom portion of the processing container 100, and thus a gas in the processing container 100 is exhausted by using a vacuum pump (not shown) provided outside the processing container 100.

Referring to FIGS. 1 and 2, dielectric plates 305, metal electrodes 310, and metal covers 320 are regularly arranged on a ceiling surface of the processing container 100. Side covers 350 are disposed around the metal electrodes 310 and the metal covers 320. The dielectric plates 305, the metal electrodes 310, and the metal covers 320 are each a plate having a substantially square shape in which corners are slightly cut. Alternatively, the dielectric plates 305, the metal electrodes 310, and the metal covers 320 may each have a diamond shape. In the present specification, the metal electrodes 310 refer to flat plates provided adjacent to the dielectric plates 305 to substantially uniformly expose the dielectric plates 305 from outer peripheral portions of the metal electrodes 310.

Accordingly, the dielectric plates 305 are sandwiched between the metal electrodes 310 and an inner wall of the lid 300. The metal electrodes 310 are electrically connected to an inner wall of the processing container 100.

48 dielectric plates 305 and metal electrodes 310 are arranged at regular pitches at positions inclined about 45° with respect to the substrate G or the processing container 100. A pitch is determined in such a manner that a length of a diagonal of one dielectric plate 305 is 0.9 times or more a distance between centers of neighboring dielectric plates 305. Accordingly, the slightly cut corners of the dielectric plates 305 are disposed adjacent to each other.

Among the metal electrodes 310 and the metal covers 320, the metal covers 320 are thicker as much as a thickness of the dielectric plates 305. Due to the shapes, heights of ceiling surfaces are almost the same, and exposed portions of the dielectric plates 305 or recessed portions near the dielectric plates 305 all have almost the same pattern.

The dielectric plates 305 are formed of alumina, and the metal electrodes 310, the metal covers 320, and the side covers 350 are formed of an aluminum alloy. Also, although the 8 dielectric plates 305 and the 8 metal electrodes 310 are arranged in 8 rows and 6 columns in the present embodiment, the present embodiment is not limited thereto and the number of the dielectric plates 305 and the metal electrodes 310 may be increased or reduced.

The dielectric plates 305 and the metal electrodes 310 are supported uniformly at 4 places by screws 325 (refer to FIG. 3). As shown in FIG. 2, a main gas passage 330 having a lattice shape in a direction perpendicular to the drawing sheet is formed between the upper lid 300a and the lower lid 300b. The main gas passage 330 distributes a gas to gas passages 325a formed in the plurality of screws 325. Tubules 335 for narrowing passages are inserted at entries of the gas passages 325a. The tubules 335 are formed of ceramic or a metal. Gas passages 310a are formed between the metal electrodes 310 and the dielectric plates 305. Gas passages 320a are also formed between the metal covers 320 and the dielectric plates 305 and between the side covers 350 and the dielectric plates 305. Front end surfaces of the screws 325 are disposed at the same height as those of lower surfaces of the metal electrodes 310, the metal covers 320, and the side covers 350 so that the distribution of plasma is not disturbed. Gas emission holes 345a opened on the metal electrodes 310 and gas emission holes 345b opened on the metal covers 320 or the side covers 350 are formed at regular pitches.

A gas output from the a gas supply source 905 passes through the gas passages 325a (branch gas passages) from the main gas passage 330, passes through first gas passages 310a in the metal electrodes 310 and second gas passages 320a in the metal covers 320 or the side covers 350, and is supplied into the processing chamber from the gas emission holes 345a and 345b. An O-ring 220 is disposed on a contact surface between the dielectric plates 305 and the lower lid 300b in the vicinity of an outer periphery of a first coaxial waveguide 610. Accordingly, the atmospheric air in the first coaxial waveguide 610 does not enter into the interior of the processing container 100.

As such, by forming a gas shower plate on a metal surface of a ceiling portion, etching a surface of a dielectric plate due to ions in plasma and deposition of reaction products in an inner wall of a processing container, which were conventionally generated, are suppressed, thereby promoting reduction of contamination or particles. Also, since a metal is easily processed unlike a dielectric substance, costs can be drastically reduced.

An inner conductor 610a is inserted into an outer conductor 610b of the first coaxial waveguide formed by digging the lid 300. Inner conductors 620a through 650a of second through fifth coaxial waveguides are inserted into outer conductors 620b through 650b of the second through fifth coaxial waveguides formed by digging the lid 300, and tops of the first through fifth coaxial waveguides are covered by a lid cover 660. The inner conductor of each coaxial waveguide is formed of copper having good thermal conductivity.

The surfaces of the dielectric plates 305 shown in FIG. 2 other than a portion where microwaves are incident on the dielectric plates 305 from the first coaxial waveguide 610 and a portion where the microwaves are emitted from the dielectric plates 305 are coated by metal films 305a. Accordingly, the propagation of microwaves is not disturbed by gaps between the dielectric plates 305 and members adjacent to the dielectric plates 305, and microwaves can be stably guided into the processing container.

As shown in FIG. 1, the dielectric plates 305 are exposed from a space between the metal electrodes 310 that are adjacent in a one-to-one correspondence manner to the dielectric plates 305 and the inner wall of the processing container 100 in which the dielectric plates 305 are not disposed (including the inner wall of the processing container 100 covered by the metal covers 320). The dielectric plates 305 and the inner wall of the processing container 100 on which the dielectric plates 305 are not disposed (including the inner wall of the processing container 100 covered by the metal covers 320) have substantially similar shapes or substantially symmetric shapes. Accordingly, power of the microwaves can be substantially uniformly supplied to the metal electrode side and the inner wall side (the metal cover 320 and side cover 350 sides) from the dielectric plates. As a result, the microwaves emitted from the dielectric plates 305 become surface waves to distribute power into halves while propagating to surfaces of the metal electrodes 310, the metal covers 320, and the side covers 350. Hereinafter, the surface waves propagating between plasma and a metal surface of an inner surface of the processing container are referred to as conductor surface waves (metal surface waves). Accordingly, since the conductor surface waves propagate over the entire ceiling surface, plasma is uniformly and stably generated under the ceiling surface of the microwave plasma processing apparatus 10 according to the present embodiment.

Since grooves 340 having octagonal shapes are formed in the side covers 350 as if the grooves 340 surround all of the 48 dielectric plates 305, the conductor surface waves propagating through the ceiling surface are suppressed from propagating to an outer side of the grooves 340. The plurality of grooves 340 may be multiply formed in parallel to one another.

An area having a center point of an adjacent metal cover 320 around one metal electrode 310 as a vertex is referred to as a cell Cel (refer to FIG. 1) hereinafter. In the ceiling surface, one cell Cel is used as a unit, and 48 cells Cel are regularly arranged, wherein the 48 cells Cel have the same pattern. Also, in the present embodiment, the size of a cell Cel is not restricted by wavelengths, which will be explained later.

A refrigerant supply source 910 is connected to a refrigerant pipe 910a inside the lid and a refrigerant pipe 910b of the inner conductor 620a of the second coaxial waveguide. Since a refrigerant supplied from the refrigerant supply source 910 circulates in the refrigerant pipes 910a and 910b and then returns to the refrigerant supply source 910, heating of the lid 300 and the inner conductor can be suppressed.

### (Multi-Branch Structure: Symmetric 8-Branch Structure)

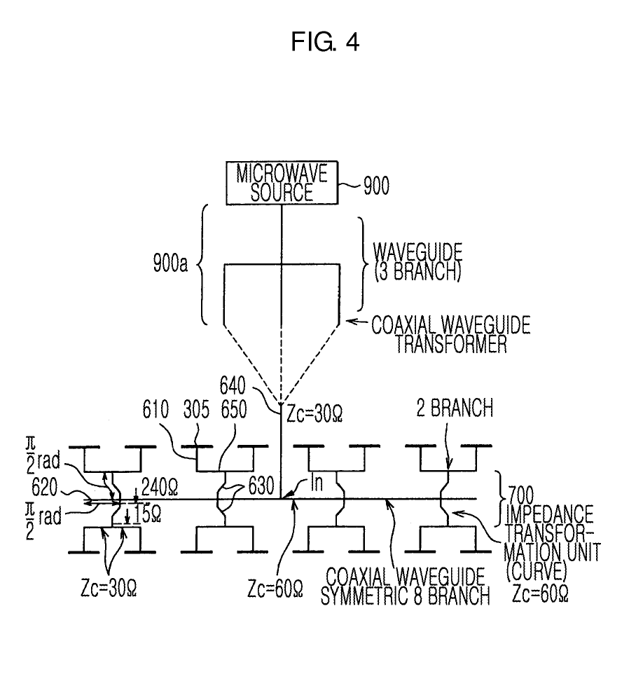

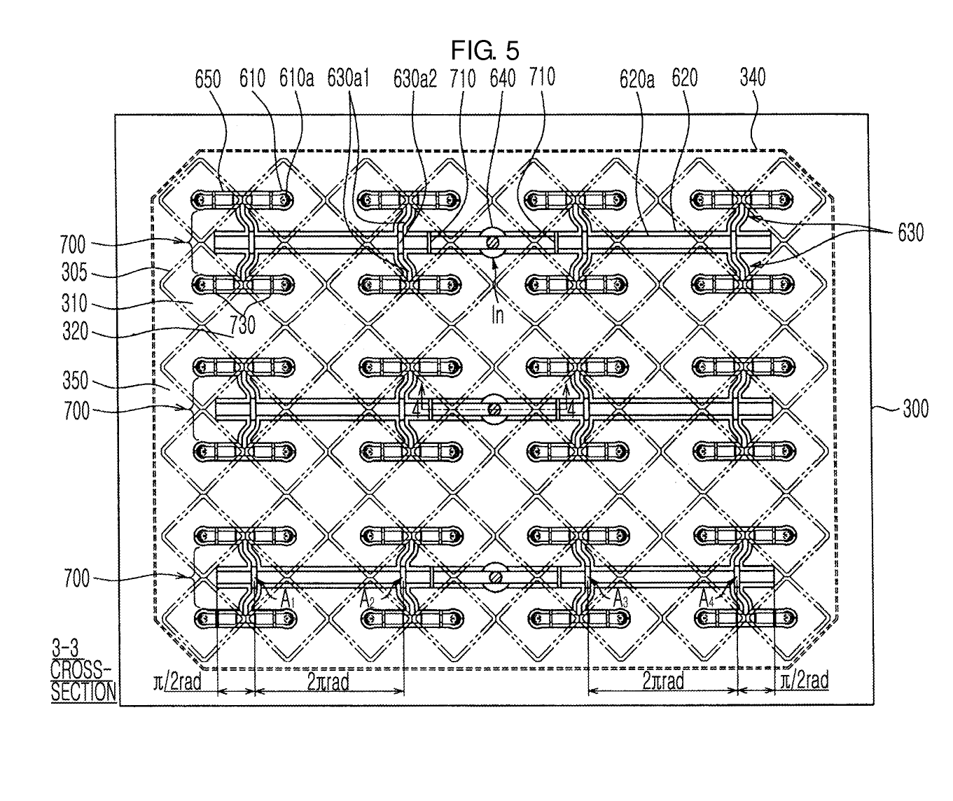

A multi-branch structure (a symmetric 8-branch structure) according to the present embodiment will now be explained with reference to FIGS. 4 and 5. FIG. 4 is a schematic view of a branch circuit including a coaxial waveguide distributor 700. FIG. 5 is a cross-sectional view taken along line 3-3 of FIG. 2.

A microwave source 900 is connected to a waveguide, is 3-branched, and transmits microwaves to the fourth coaxial waveguide 640 through a coaxial waveguide transformer. The fourth coaxial waveguide 640 is 2-branched (T-branched) to be connected to the second coaxial waveguide 620. A portion of the second coaxial waveguide 620 on which the microwaves are incident from the fourth coaxial waveguide 640 is referred to as an input portion In of the second coaxial waveguide hereinafter. The coaxial waveguide distributor 700 has a multi-branch structure including the second coaxial waveguide 620 having the input portion In and the third coaxial waveguides 630 that are connected at 4 places to the second coaxial waveguide 620 and extend non-perpendicularly. 2 of the third coaxial waveguides 630 are connected to the second coaxial waveguide 620 at a connected portion between the second coaxial waveguide 620 and each of the third coaxial waveguides 630. In the present embodiment, 8 of the third coaxial waveguides 630 are connected to the second coaxial waveguide 620. Each of 8 of the third coaxial waveguides 630 is T-branched to a fifth coaxial waveguide 650. Both end portions of the fifth coaxial waveguide 650 are connected to the first coaxial waveguides 610. Terminal ends of the first coaxial waveguides 610 are connected to the dielectric plates 305.

Accordingly, microwaves of 915 MHz output from one microwave source 900 pass through an isolator, a directional coupler, a matcher (not shown), a waveguide 3-distributor, and 3 coaxial waveguide transformers, are transmitted through the fourth coaxial waveguide 640, and are transmitted while power is uniformly distributed by the coaxial waveguide distributor 700 including the second coaxial waveguide 620 and 8 of the third coaxial waveguides 630. The microwaves transmitted through the third coaxial waveguides 630 are transmitted to the dielectric plates 305 through the fifth coaxial waveguide 650 and the first coaxial waveguides 610, and are emitted into the processing container from the dielectric plates 305 exposed from the peripheries of the metal electrodes 310. In the present apparatus, 3 of the second coaxial waveguides 320 are arranged at regular pitches in parallel to one another.

Although 8 of the third coaxial waveguides 630 are connected to the second coaxial waveguide 620 in the present embodiment, 3 or more of the third coaxial waveguides 630 may be connected to the second coaxial waveguide 620. A branched portion formed in the coaxial waveguide distributor 700 according to the present embodiment has a symmetric multi-branch structure. Here, the term “symmetric multi-branch structure” refers to a structure where the number and connected positions of the third coaxial waveguides 630 connected to a space between the end of one branch and the input portion In at the center of the inner conductor of the second coaxial waveguide and the number and connected positions of the third coaxial waveguides 630 connected to a space between the end of another branch and the input portion In at the center of the inner conductor of the second coaxial waveguide are the same, and 3 or more branches are symmetric with respect to the input portion In.

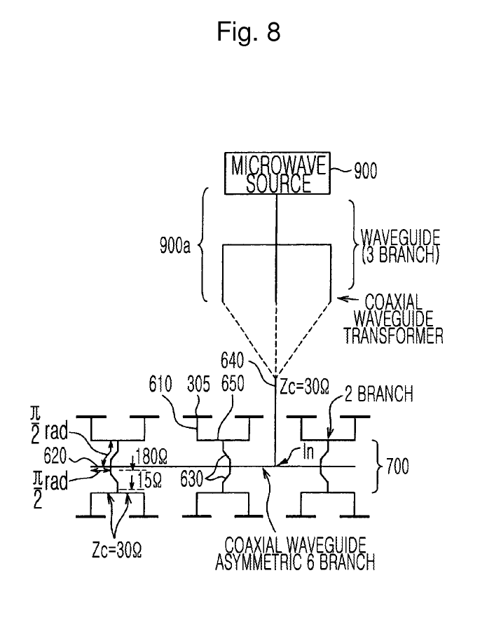

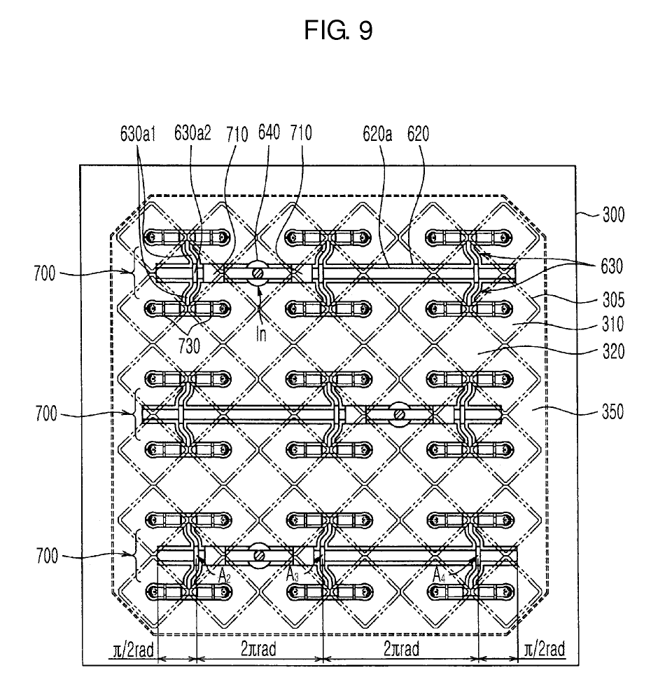

Meanwhile, a branched portion formed in the coaxial waveguide distributor 700 according to a second embodiment which will be explained later has an asymmetric multi-branch structure. The term “asymmetric multi-branch structure”, for example, as shown in FIGS. 8 and 9, refers to a structure where the number and connected positions of third connected cables 630 connected to a space between the end of one branch and the input portion In at the center of the inner conductor of the second coaxial waveguide and the number and connected positions of the third coaxial waveguides 630 connected to a space between the end of another branch and the input portion In at the center of the inner conductor of the second coaxial waveguide are not the same, and 3 or more branches are not symmetric with respect to the input portion In.

As shown in FIG. 5, the input portion In is a center point between a connected portion A₂ and a connected portion A₃ of connected portions A₁ through A₄ between the inner conductor 620a and the inner conductors 630a. When an electrical length between the connected portion A₁ and the connected portion A₂ and between the connected portion A₃ and the connected portion A₄ without the input portion In therebetween is an integer multiple of π rad, amplitudes of microwaves transmitted to all of the third coaxial waveguides 630 are the same. Also, when such an electrical length is an odd multiple of π rad, a difference between phases of microwaves transmitted to the third coaxial waveguides 630 connected to the connected portion A₁ and the connected portion A₂ and to the third coaxial waveguides 630 connected to the connected portion A₃ and the connected portion A₄ is π rad. Meanwhile, when such an electrical length is an even multiple of π rad, that is, an integer multiple of 2π rad, phases of microwaves transmitted to all of the third coaxial waveguides 630 are the same. In the present embodiment, since microwaves should be in phase, it is preferable that such an electrical length is an integer multiple of 2π rad. Also, since a propagation mode (TEM mode) is changed around a connected portion, an electrical length is changed. Accordingly, actually, a distance between the connected portion A₁ and the connected portion A₂ and a distance between the connected portion A₃ and the connected portion A₄ are set to be several mm longer than guide wavelength λg₂ (=327.6 mm) of the second coaxial waveguide 620.

A structure of the coaxial waveguide distributor 700 will be explained in detail with reference to FIG. 5. The center of the second coaxial waveguide 620 is connected to the fourth coaxial waveguide 640. From the input portion In of the second coaxial waveguide 620 to end portions of the second coaxial waveguide 620, 2 of the third coaxial waveguides 630 are connected and extends in a curved shape with respect to each end portion of the second coaxial waveguide 620. It is preferable that the number of the third coaxial waveguides 630 connected to a space between the input portion In of the second coaxial waveguide 620 and an end portion of the second coaxial waveguide 620 is not greater than 2. This is because although the frequency of microwaves is changed, the balance of power shared by the third coaxial waveguides 630 is hard to be broken.

The inner conductor 620a and the outer conductor 620b of the second coaxial waveguide are short-circuited at both ends of the second coaxial waveguide 620, and an electrical length in a space between an end portion of the second coaxial waveguide 620 and a connected portion between the second coaxial waveguide 620 and the third coaxial waveguides 630 closest to the end portion of the second coaxial waveguide 620 is substantially equal to an odd multiple (here, 1 time) of π/2 rad. Accordingly, this space may be regarded as a distributed line having one end short-circuited. In this regard, in the case of a distributed line having an electrical length of π/2 rad with one end short-circuited, an impedance observed from the one end appears to be infinite. Accordingly, in the transmission of microwaves, since there seems no portion between an end portion of the second coaxial waveguide 620 and the connected portion, a transmission line can be easily designed.

Each of the fifth coaxial waveguides 650 is connected to an output end of the inner conductor 630a (an end portion of an output side of a rod 630a1), forming a T-branch. The first coaxial waveguides 610 are perpendicularly connected to both end portions of each of the fifth coaxial waveguides 650 inwardly on a drawing sheet. In this configuration, microwaves are input from the input portion In of the second coaxial waveguide 620 to the coaxial waveguide distributor 700, are transmitted through the second coaxial waveguide 620, are multi-branched and distributed to the third coaxial waveguides 630, pass through the fifth coaxial waveguides 650 and the first coaxial waveguides 610, and are emitted from adjacent plurality of dielectric plates 305 into the processing container.

### (Fourth Coaxial Waveguide and T-Branching)

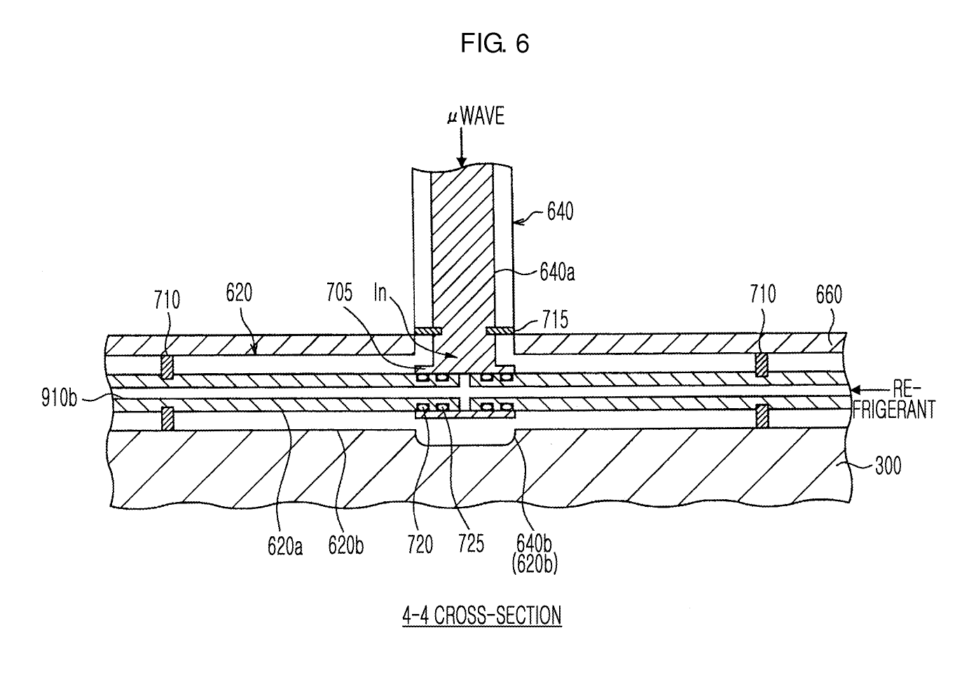

FIG. 6 is a cross-sectional view taken along line 4-4 of FIG. 5, showing a connected portion between the fourth coaxial waveguide 640 and the second coaxial waveguide 620. The connected portion between the fourth coaxial waveguide 640 and the second coaxial waveguide 620 is 2-branched (T-branched) in a T-like shape. A front end of the inner conductor 640a of the fourth coaxial waveguide has a pipe 705 shape, and the inner conductor 620a passes through the inside thereof. Accordingly, the inner conductor 640a of the fourth coaxial waveguide and the inner conductor 620a of the second coaxial waveguide are closely adhered to each other. Microwaves are transmitted from the fourth coaxial waveguide 640 to the second coaxial waveguide 620.

Grooves are formed in outer circumferential portions of the inner conductor 620a at both sides of the fourth coaxial waveguide 640, and dielectric rings 710 are inserted into the grooves. Grooves are also formed in an outer circumferential portion of the inner conductor 640a of the fourth coaxial waveguide, and dielectric rings 715 are inserted into the grooves. The dielectric rings 710 and 715 are formed of Teflon (registered trademark). Accordingly, the inner conductors 620a and 640a of the second and fourth coaxial waveguides are respectively supported by the outer conductors 620b and 640b.

The outer conductor 640b of the fourth coaxial waveguide passes through the second coaxial waveguide, and protrudes in a round bowl shape beyond the outer conductor 620b of the second coaxial waveguide. As such, by making a portion of the outer conductor at a branched portion (connected portion) thicker than a portion of the outer conductor at the other portion of the outer conductor of the coaxial waveguide (here, the second coaxial waveguide 620) at an output side of the 2-branched portion, a space between the inner conductor 620a and the outer conductor 620b of the second coaxial waveguide at the connected portion increases so that reflection of microwaves is suppressed when transmitted through the branched portion.

On a contact surface between the inner conductor 620a and the pipe 705 portion of the inner conductor 640a, a shield spiral 720 and an O-ring 725 are respectively disposed on an outer side and an inner side. The shield spiral 720 is disposed to improve electrical connection between the inner conductor 620a of the second coaxial waveguide and the inner conductor 640a of the fourth coaxial waveguide, and the O-ring 725 is disposed to prevent a refrigerant from leaking to the outside from the refrigerant passage 910b.

The inner conductor 640a of the fourth coaxial waveguide is slidably connected in a longitudinal direction of the second coaxial waveguide 620. Although the inner conductor 630a of each of the third coaxial waveguides is fixed with a screw to the second coaxial waveguide 620, the inner conductor 630a of the third coaxial waveguide 630 may be slidably connected in the longitudinal direction of the second coaxial waveguide 620, in order not to apply stress to each coaxial waveguide upon the thermal expansion of a member due to heat.

### (Characteristic Impedance)

In 2-branching, since two coaxial waveguides at an output side are connected in parallel to a coaxial waveguide at an input side, in order to match impedances between input and output, a characteristic impedance of the coaxial waveguide at the input side may be a half of a characteristic impedance at the output side. In the present embodiment, since a characteristic impedance of the fourth coaxial waveguide 640 (coaxial waveguide at the input side) is set to 30 Ω and a characteristic impedance of the second coaxial waveguide 620 (coaxial waveguide at the output side) is set to 60 Ω, the relationship is satisfied. Accordingly, microwaves of large power can be transmitted by suppressing reflection at the branched portion.

### (Connected Portion Between Third Coaxial Waveguides and Second Coaxial Waveguide)

Referring to FIG. 2, in the inner conductor 630a of each of the third coaxial waveguides, the rod 630a1 is fixed by a screw S to an inner conductor connection plate 630a2. As such, at a connected portion between the second coaxial waveguide 620 and the third coaxial waveguide 630, the third coaxial waveguide 630 (the rod 630a1) is connected to the second coaxial waveguide 620 to face the second coaxial waveguide 620. Also, only one or two or more of the third coaxial waveguides 630 may be connected at each branched portion. Also, each of the third coaxial waveguides 630 may be connected to face the second coaxial waveguide 620 as in the present embodiment, or may not face the second coaxial waveguide 620.

From among the inner conductor 630a of each of the third coaxial waveguides, a portion connected to the inner conductor 620a of the second coaxial waveguide (a portion of the inner conductor connection plate 630a2) is narrower than other portions, in order to reduce the disturbance of a transmission state of microwaves to be transmitted through the second coaxial waveguide. Also, an electrical length of the third coaxial waveguides 630 may be adjusted by changing a length and a thickness of the narrowed portion. By making the inner conductor 630a of each of the third coaxial waveguides narrower than the inner conductor 620a of the second coaxial waveguide or making the outer conductor 630b of each of the third coaxial waveguides narrower than the outer conductor 620b of the second coaxial waveguide, the disturbance of a transmission state of microwaves is reduced. The inner conductor connection plate 630a2 and the inner conductor 620a of the second coaxial waveguide are fixed by brazing or soldering. Also, the third coaxial waveguides 630 function as an impedance transformation mechanism, which will be explained later.

### (Fifth Coaxial Waveguide and T-Branching)

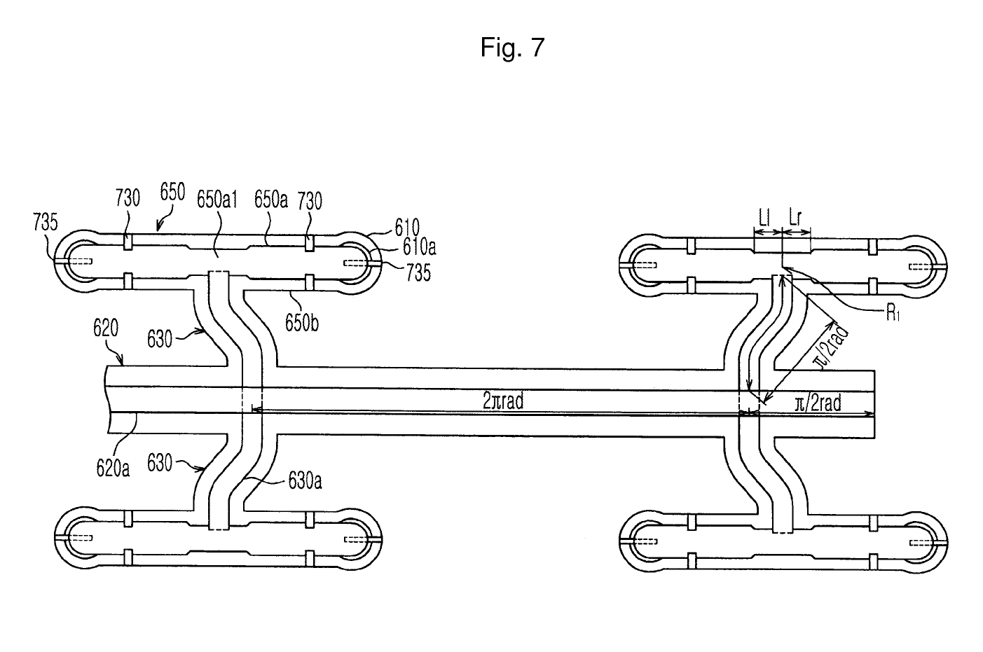

A T-branch structure by the third and fifth coaxial waveguides 630 and 650 will now be explained with reference to FIG. 7. Each of the third coaxial waveguides 630 connects the second coaxial waveguide 620 and the fifth coaxial waveguide 650 while being curved. The inner conductor 650a of the fifth coaxial waveguide is formed of copper like the inner conductors 620a and 630a of the second and third coaxial waveguides. A connected portion between the inner conductors 630a and 650a of the third and fifth coaxial waveguides is fixed by soldering or brazing in a state where the inner conductor 630a of each of the third coaxial waveguides is inserted into a recess portion of the inner conductor 650a of the fifth coaxial waveguide.

Grooves are formed at both sides of the T-branch structure in an outer circumferential portion of the inner conductor 650a of the fifth coaxial waveguide, and dielectric rings 730 are inserted into the grooves. Accordingly, the inner conductor 650a of the fifth coaxial waveguide is supported to the outer conductor 650b. The inner conductor 650a of the fifth coaxial waveguide is also supported from side portions by dielectric rods 735. The dielectric rods 735 are inserted into holes formed in the inner conductor 650a of the fifth coaxial waveguide to fix the inner conductor 610a of each of the first coaxial waveguides to the fifth coaxial waveguide 650. The dielectric rings 730 and the dielectric rods 735 are formed of Teflon.

### (Impedance Transformation Mechanism)

An impedance transformation mechanism of the third coaxial waveguides will now be explained. In order to remove reflection in the coaxial waveguide distributor 700, an impedance obtained by observing a third coaxial waveguide side from a connected portion between the second coaxial waveguide 620 and each of the third coaxial waveguides 630 may be a desired real number. When an output side of each of the third coaxial waveguides 630 is matched, an impedance obtained by observing the third coaxial waveguide side from the connected portion may be a real number by designing that an electrical length of each of the third coaxial waveguides 630 is substantially π/2 rad. Also, an impedance obtained by observing the third coaxial side from the connected portion may be a desired value by changing a characteristic impedance of the third coaxial waveguides.

As shown in FIG. 2, in the inner conductor 630a of the aforesaid third coaxial waveguides, a portion connected with the inner conductor 620a of the second coaxial waveguide (the inner conductor connection plate 630a2) is narrower than another portion (the rod 630a1 portion). As such, an electrical length of each of the third coaxial waveguides 630 may be extended by narrowing the inner conductor 630a of each of the third coaxial waveguides.

Also, although not shown, an electrical length of each of the third coaxial waveguides 630 may be extended by narrowing a connected portion between the inner conductor 630a of each of the third coaxial waveguides and the inner conductor 650a of the fifth coaxial waveguide or thickening the outer conductor 630b.

Also, an electrical length of each of the third coaxial waveguides 630 may be lengthened by narrowing a connected portion between the inner conductor 650a of the fifth coaxial waveguide and the inner conductor 630a of each of the third coaxial waveguides like a narrowed portion 650a1 of FIG. 7 or by thickening the outer conductor 650b.

As described above, an electrical length of the third coaxial waveguides can be adjusted by forming a narrowed portion or a thickened portion in each of the third coaxial waveguides 630 and adjusting a length or a thickness of the narrowed portion or the thickened portion of each of the third coaxial waveguides 630. Also, an electrical length of a coaxial waveguide (here, the second or fifth coaxial waveguide) connected to each of the third coaxial waveguides may be adjusted by adjusting a length or a thickness of the coaxial waveguide connected to each of the third coaxial waveguides. Due to such adjustment means (impedance transformation mechanism), a cell pitch Pi1 (refer to FIG. 1) in a direction perpendicular to the second coaxial waveguide 620 can be relatively freely determined. Also, a cell pitch Pi2 in a direction horizontal to the second coaxial waveguide 620 may be relatively freely determined by curving the third coaxial waveguides 630.

Accordingly, vertical and horizontal sizes of a cell can be freely determined in accordance with a substrate size without being restricted by guide wavelengths of microwaves. In general, when a plasma excitation area Ea is about 60 to 80 mm larger than a substrate size, uniform plasma processing can be performed. Accordingly, when a plasma excitation area Ea is slightly larger than a substrate size and isn't increased too much to satisfy the condition, power consumption can be reduced. Also, the apparatus itself can be prevented from being increased too much.

### (Impedance Buffer Portion)

As an inner conductor is thickened, a characteristic impedance is decreased, and as an inner conductor is narrowed, the characteristic impedance is increased.

Accordingly, if the inner conductor 630a of each of the third coaxial waveguides and the inner conductor 650a of the fifth coaxial waveguide which have different thicknesses are directly connected to each other, since a characteristic impedance is greatly changed, reflection at a connected portion is increased. Accordingly, the narrowed portion 650a1 of the connected portion between the inner conductor 650a of the fifth coaxial waveguide and the inner conductor 630a of each of the third coaxial waveguides functions to reduce reflection. As such, since the narrowed portion 650a1 functions as an impedance buffer portion and thus can slowly gradually change a characteristic impedance to suppress the reflection of microwaves and connect the third coaxial waveguides and the fifth coaxial waveguide, microwaves can be easily introduced into the left and the right of the fifth coaxial waveguide 650. Also, by varying not only a thickness of the narrowed portion 650a1 but also a length Lr of a right curve and a length Ll of a left curve from a center point R1 of the inner conductor 650a of the fifth coaxial waveguide in accordance with the curved shape of each of the third coaxial waveguides 630, microwaves having equal power can be transmitted to the left and the right of the fifth coaxial waveguide 650.

In the case of a symmetric multi-branch structure, impedances obtained by observing both ends from the input portion In of the second coaxial waveguide 620 can be matched, and an impedance obtained by observing a load side from the fourth coaxial waveguide 640 can be matched. As a result, since there is no reflection when observing from an input side of the coaxial waveguide distributor 700, microwaves of large power can be transmitted. When the following conditions are satisfied, an impedance obtained by observing a load side from the second coaxial waveguide 620 can be matched.

That is, when an impedance obtained by observing a plasma side from the first coaxial waveguides 610 is matched, an impedance obtained by observing an output side from an output end of the third coaxial waveguides 630 is substantially resistive, and when a resistance obtained by observing the output side from the output end of the third coaxial waveguides 630 is Rᵣ₅, the number of the third coaxial waveguides 630 connected to a space between the input portion In of the second coaxial waveguide 620 and an end portion of the second coaxial waveguide 620 is Nₛ, and a characteristic impedance of the second coaxial waveguide 620 is Z_{c2}, a characteristic impedance Z_{c3} of the third coaxial waveguides 630 is substantially equal to (Rᵣ₅×Nₛ×Z_{c2})^{1/2} and an electrical length of the third coaxial waveguides 630 is π/2 rad. For example, in the case of the 8-branch structure shown in FIG. 4, since 2 of the fifth coaxial waveguides 650 having a characteristic impedance of 30 Ω are connected in parallel to an output end of each of the third coaxial waveguides 630, Rᵣ₅=15 Ω. Also, when Nₛ=4 and Z_{c2}=60 Ω, Z_{c3} may be 60 Ω.

Also, when an impedance obtained by observing a third coaxial side from a connected portion between the second coaxial waveguide 620 and each of the third coaxial waveguides 630 is substantially resistive, a resistance obtained by observing the third coaxial waveguide side from the connected portion between the second coaxial waveguide 620 and each of the third coaxial waveguides 630 is Rᵣ₃, the number of the third coaxial waveguides 630 connected to a space between the input portion In of the second coaxial waveguide 620 and one end of the second coaxial waveguide 620 is Nₛ, and a characteristic impedance of the second coaxial waveguide 620 is Z_{c2}, the characteristic impedance Z_{c2}of the second coaxial waveguide 620 is substantially equal to Rᵣ₃/Nₛ.

For example, in the case of the 8-branch structure shown in FIG. 4, since Rᵣ₃=240 and Z_{c2}=240/4=60 Ω, the above relationship is satisfied.

### Embodiment 2

### (Asymmetric 6-Branch Structure)

A branch circuit of a G4.5 glass substrate according to a second embodiment will now be explained with reference to FIGS. 8 and 9. FIG. 8 is a schematic view of a branch circuit including the coaxial waveguide distributor 700 according to the present embodiment. FIG. 9 shows a ceiling surface of the microwave plasma processing apparatus 10 according to the present embodiment. The present embodiment has a multi-branch structure in which a coaxial waveguide is 6-branched in an asymmetric manner. The size of the G4.5 glass substrate is 730×920 mm.

In the present embodiment, as shown in FIG. 8, a transmission line 900a includes a waveguide, a coaxial waveguide transformer, and a plurality of coaxial waveguides. Microwaves generated from one microwave source 900 are 3-branched at the waveguide, are transmitted to the coaxial waveguide transformer, and are transmitted to the coaxial waveguide distributor 700 through the fourth coaxial waveguide 640. The coaxial waveguide distributor 700 has a multi-branch structure including the third coaxial waveguides 630 that are 6-branched in an asymmetric manner from the second coaxial waveguide 620 having the input portion In.

As shown in FIG. 9, 36 cells in total are uniformly arranged in such a manner that 6 cells are arranged in a substrate longer direction and in a substrate shorter direction. The input portion In is located at a center point between the connected portion A₂ and the connected portion A₃ or a center point between the connected portion A₃ and the connected portion A₄. As described above, in the case of a symmetric multi-branch structure, impedances obtained by observing both ends from the input portion In of the second coaxial waveguide 620 can be respectively matched and an impedance obtained by observing a load side from the fourth coaxial waveguide 640 can be also matched.

However, in the case of an asymmetric multi-branch structure, if impedances obtained by observing both ends from the input portion In of the second coaxial waveguide 620 are respectively matched, since power of microwaves transmitted to the left and the right becomes the same, power of microwaves supplied to cells becomes different. Accordingly, impedances obtained by observing both ends from the input portion In of the second coaxial waveguide 620 cannot be matched. However, if the following conditions are satisfied, an impedance obtained by observing a load side from the fourth coaxial waveguide 640 can be matched. As a result, microwaves of large power can be transmitted.

That is, when the fourth coaxial waveguide 640 having a characteristic impedance Z_{c4} is connected to the input portion In of the second coaxial waveguide 620 and an impedance obtained by observing a plasma side from the first coaxial waveguides 610 is matched, and when an impedance obtained by observing an output side from an output end of the third coaxial waveguides 630 is substantially resistive, an resistance obtained by observing the output side from the output end of the third coaxial waveguides 630 is Rᵣ₅ and the number of the third coaxial waveguides 630 connected to the second coaxial waveguide 620 is Nₜ, a characteristic impedance Z₃ of the third coaxial waveguides 630 is substantially equal to (Rᵣ₅×Nₜ×Z_{c4})^{1/2} and an electrical length of the third coaxial waveguides 630 is π/2 rad. For example, in the case of the 6-branch structure shown in FIG. 8, since 2 fifth coaxial waveguides 650 having a characteristic impedance of 30 Ω are connected in parallel to an output end of each of the third coaxial waveguides 630, Rᵣ₅=15 Ω. Also, when Nₜ=6 and Z_{c4}=30 Ω, Z_{c3} may be 52 Ω.

Also, when an impedance obtained by observing a third coaxial side from a connected portion between the second coaxial waveguide 620 and each of the third coaxial waveguides 630 is substantially resistive, a resistance obtained by observing the third coaxial waveguide side from the connected portion is Rᵣ₃, and the number of the third coaxial waveguides 630 connected to the second coaxial waveguide 620 is Nₜ, a characteristic impedance Z_{c4} is substantially equal to Rᵣ₃/Nₜ.

For example, in the case of the 6-branch structure shown in FIG. 8, since Rᵣ₃=180 and Z_{c4}=180/6=30 Ω, the above relationship is satisfied.

In the case of a symmetric multi-branch structure, since impedances obtained by observing both ends from the input portion In of the second coaxial waveguide 620 can be matched and thus standing waves do not arise at the connected portions A₂ through A₃, an interval between the connected portions A₂ through A₃ is arbitrary. Meanwhile, in the case of an asymmetric branch structure, since standing waves arise at the connected portions A₂ through A₃, an electrical length between the connected portions A₂ through A₃ must be an integer multiple (1 time in the present embodiment) of 2π rad.

However, if a coaxial waveguide is connected to an input portion In, since a propagation mode is collapsed around a connected portion, an electrical length is changed. In order to correct the change in the electrical length, the dielectric rings 710 formed of Teflon are disposed between the input portion In and the connected portion A₂ and between the input portion In and the connected portion A₃. By optimizing thicknesses, positions, and permittivities of the dielectric rings 710, even in the asymmetric multi-branch structure, microwaves having desired amplitude and phase can be transmitted to an end of a branch.

### Embodiment 3

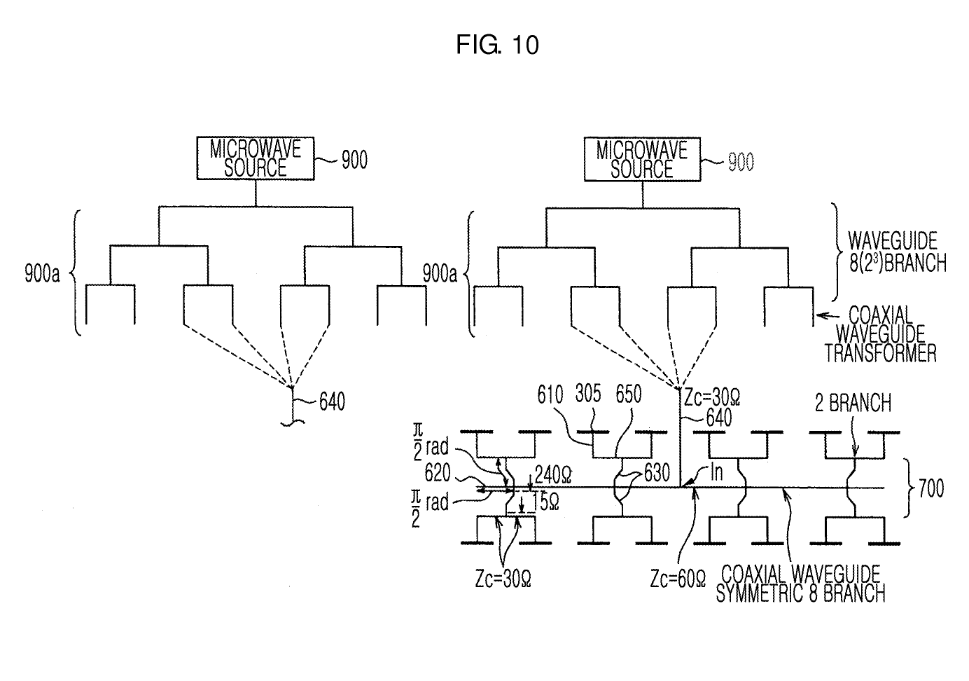

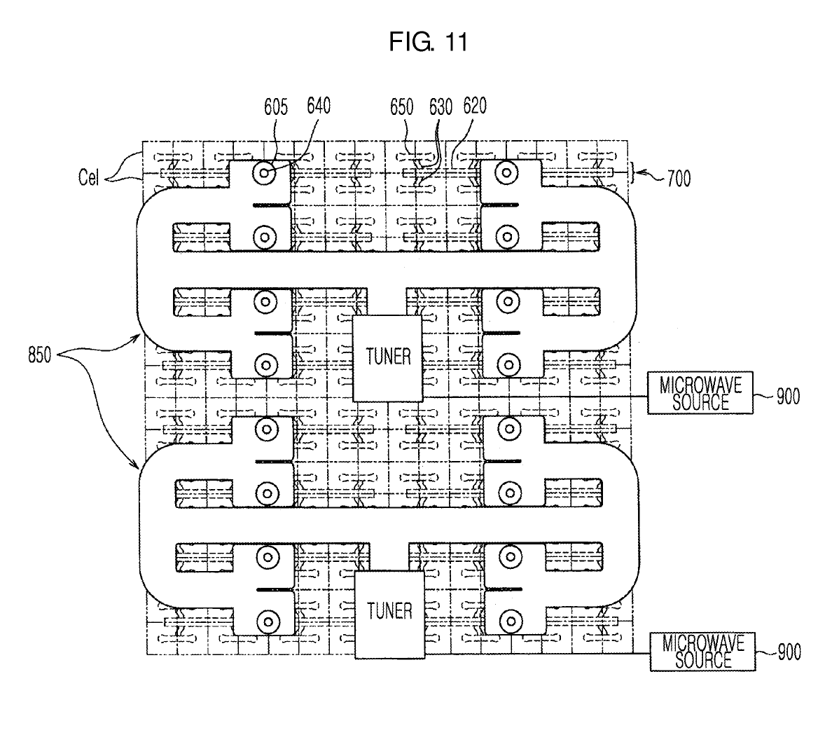

A branch circuit of a G10 glass substrate according to a third embodiment of the present invention will now be explained with reference to FIGS. 10 and 11. FIG. 10 is a schematic view of a branch circuit including the coaxial waveguide distributor 700. FIG. 11 shows a waveguide distributor 850 held on the microwave plasma processing apparatus. The present embodiment has a multi-branch structure in which a coaxial waveguide is 8-branched in a symmetric manner. The size of the G10 glass substrate is 2880×3080 mm.

The waveguide distributor 850 has a plane shape and is 2×2×2-branched in a tournament manner. The waveguide is branched in a symmetric manner at both sides from the microwave source 900 and a tuner. Since the waveguide distributor 850 has a plane shape, a thickness of the waveguide (a length in a direction perpendicular to the drawing sheet of FIG. 11) is low and thus the waveguide can be easily held on the apparatus.

256 cells in total are uniformly arranged in such a manner that 16 cells are arranged in a substrate longer direction and a substrate shorter direction. Coaxial waveguide-symmetric 8 branches are installed in 2 rows and 8 columns.

### (Modified Example of Impedance Transformation Mechanism)

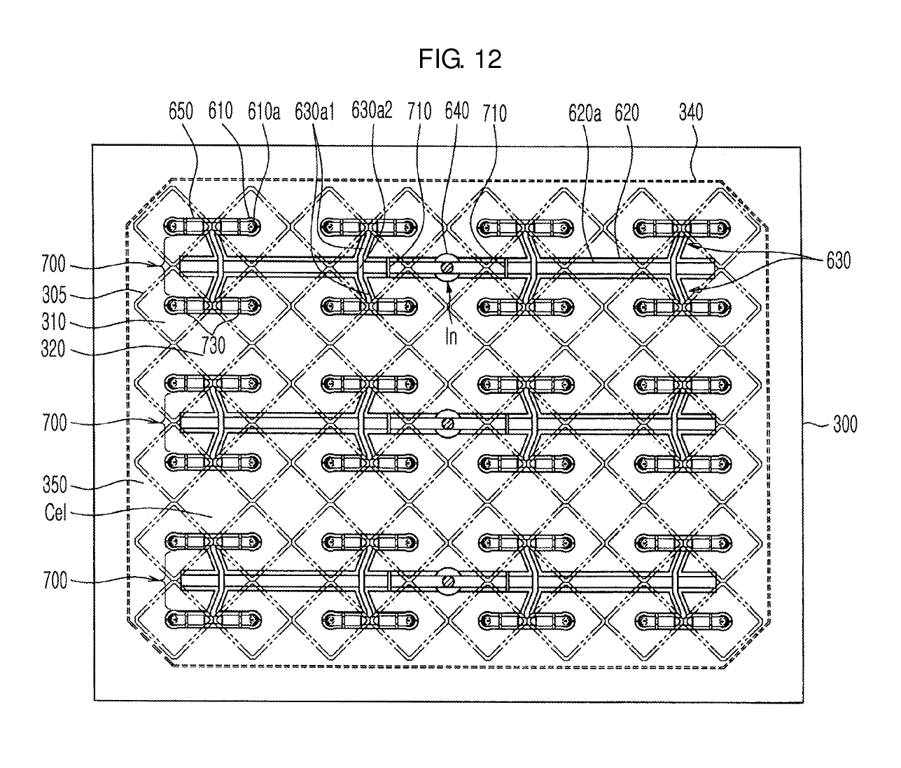

A modified example of an impedance transformation mechanism will now be briefly explained with reference to FIG. 12. As shown in FIG. 5, while the third coaxial waveguides 630 are curved in the previous embodiments, the third coaxial waveguides 630 according to the present modified example are obliquely connected to the second coaxial waveguide. Even in this case, by enabling the third coaxial waveguides 630 to function as an impedance transformation mechanism to suppress reflection when observing from a distributor input side, microwaves of large power can be transmitted.

### Embodiment 4

### (Modified Example of Coaxial Waveguide Distributor)

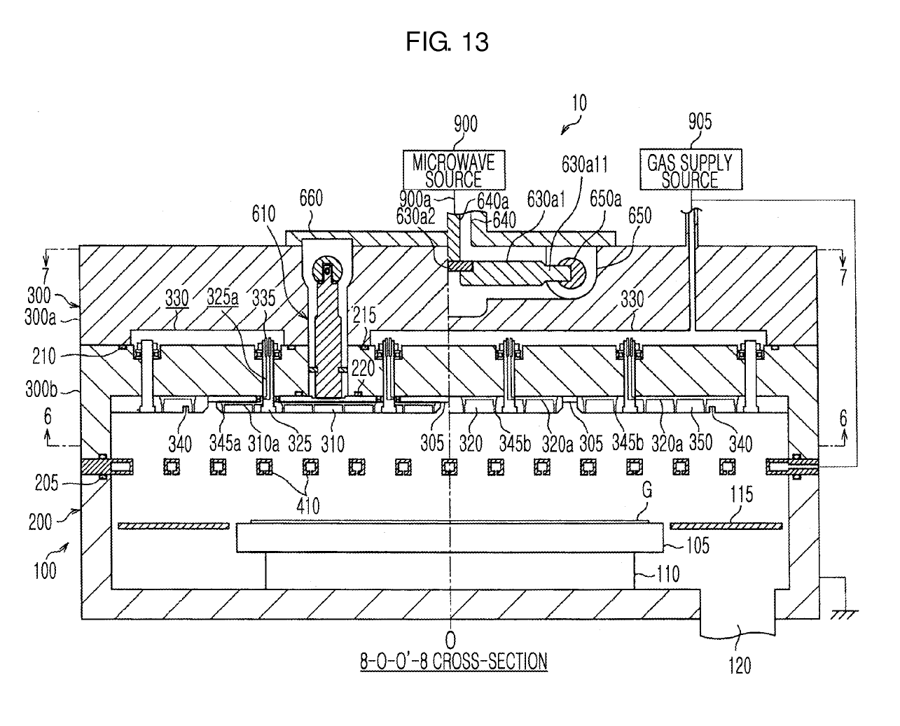

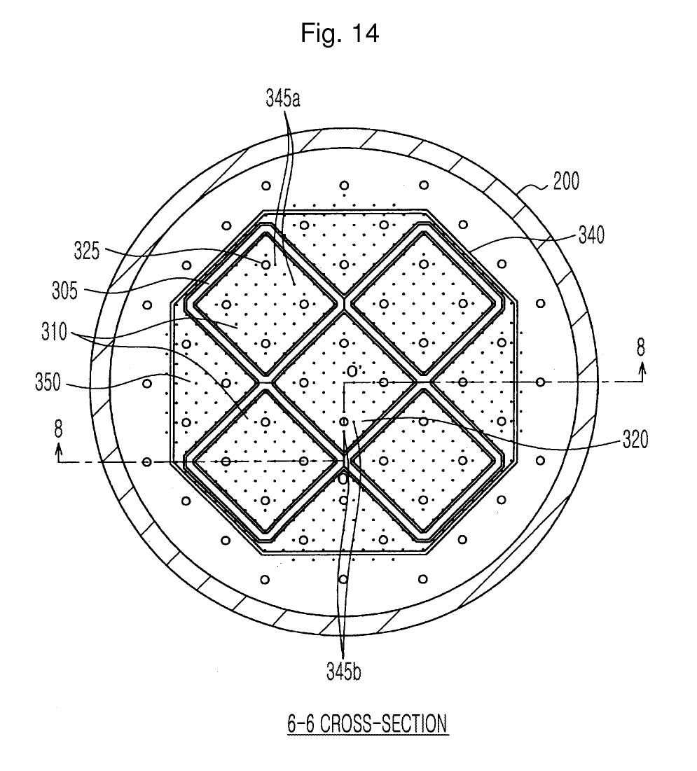

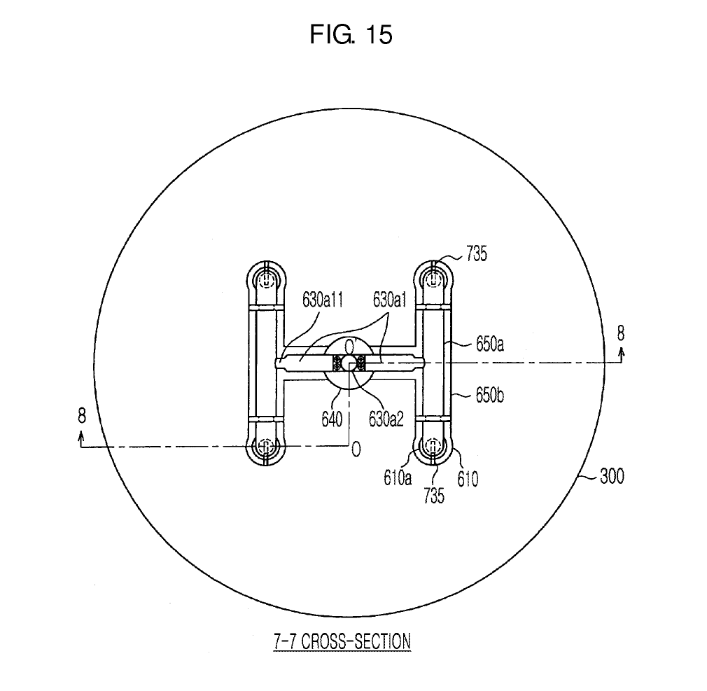

Finally, a modified example of the coaxial waveguide distributor 700 according to a fourth embodiment of the present invention will now be briefly explained with reference to FIGS. 13 through 15. FIG. 13 is a cross-sectional view of the microwave plasma processing apparatus according to the present embodiment. FIG. 13 is a cross-sectional view taken along line 8-0-0′-8 of FIG. 14. FIG. 14 is a cross-sectional view taken along line 6-6 of FIG. 13. FIG. 15 is a cross-sectional view taken along line 7-7 of FIG. 13. The microwave plasma processing apparatus 10 according to the fourth embodiment is an apparatus for a semiconductor substrate having a wafer size of 300 mm in diameter.

In the present embodiment, the fourth coaxial waveguide 640 is T-branched to the third coaxial waveguides 630 (the rod 630a1 and the inner conductor connection plate 630a2), and also, each of the third coaxial waveguides 630 is T-branched to the fifth coaxial waveguide 650. A branched portion of the third coaxial waveguides 630 has a narrowed portion 630a11 narrower than other portions. The T-branching from each of the third coaxial waveguides 630 to the fifth coaxial waveguides 650 is basically the same as the T-branching in FIG. 5, and the third coaxial waveguides 630 performs impedance transformation. However, in the present embodiment, the third coaxial waveguides 630 are not curved, and the inner conductor 630a of each of the third coaxial waveguides is perpendicularly connected to the inner conductor 650a of the fifth coaxial waveguide.

2 of the fifth coaxial waveguides 650 having a characteristic impedance of 30 Ω are connected in parallel to an output end of each of the third coaxial waveguides. Accordingly, when an impedance obtained by observing a plasma side from the first coaxial waveguides 610 is matched, an impedance obtained by observing the output side from the output end of each of the third coaxial waveguides 630 is 30/2=15 Ω.

Meanwhile, a characteristic impedance of the fourth coaxial waveguide 640 is 50 Ω. Accordingly, when an impedance obtained by observing a third coaxial waveguide side from a connected portion between the fourth coaxial waveguide and the third coaxial waveguides is 50×2=100 Ω, since reflection in the distributor is removed, microwaves of large power can be transmitted. Impedance transformation from 15 Ω to 100 Ω is performed by the third coaxial waveguides having an electrical length of π/2 rad.

In the present embodiment, the narrowed portion 630a11 is formed at an inner conductor 630a side of the connected portion. An electrical length of the third coaxial waveguides 630 is adjusted according to a diameter or a length of the narrowed portion 630a11.

Also, from among an outer conductor of a coaxial waveguide at an output side constituting the 2-branch structure (the outer conductor 650b of the fifth coaxial waveguide of FIG. 15), a connected portion may be thicker than other portions.

According to the microwave plasma processing apparatus 10 according to the aforesaid first through third embodiments and the modified examples, at least one stage of the coaxial waveguide distributor 700 is multi-branched from the second coaxial waveguide 620 to 3 or more of the third coaxial waveguides 630 connected non-perpendicularly to the second coaxial waveguide 620. Since the third coaxial waveguides 630 have mechanisms for adjusting a characteristic impedance, a characteristic impedance of an input side (an electromagnetic wave source side) of the third coaxial waveguides 630 can be matched to a characteristic impedance of an output side (a plasma side) of the third coaxial waveguides 630. As a result, microwave transmission efficiency can be improved.

Also, according to the microwave plasma processing apparatus 10 according to the fourth embodiment, in at least one stage of the coaxial waveguide distributor 700, by enabling a characteristic impedance of a coaxial waveguide at an input side to be different from a characteristic impedance of a coaxial waveguide at an output side, an impedance at a branched portion can be matched. As a result, microwaves of large power can be transmitted.

### Embodiment 5

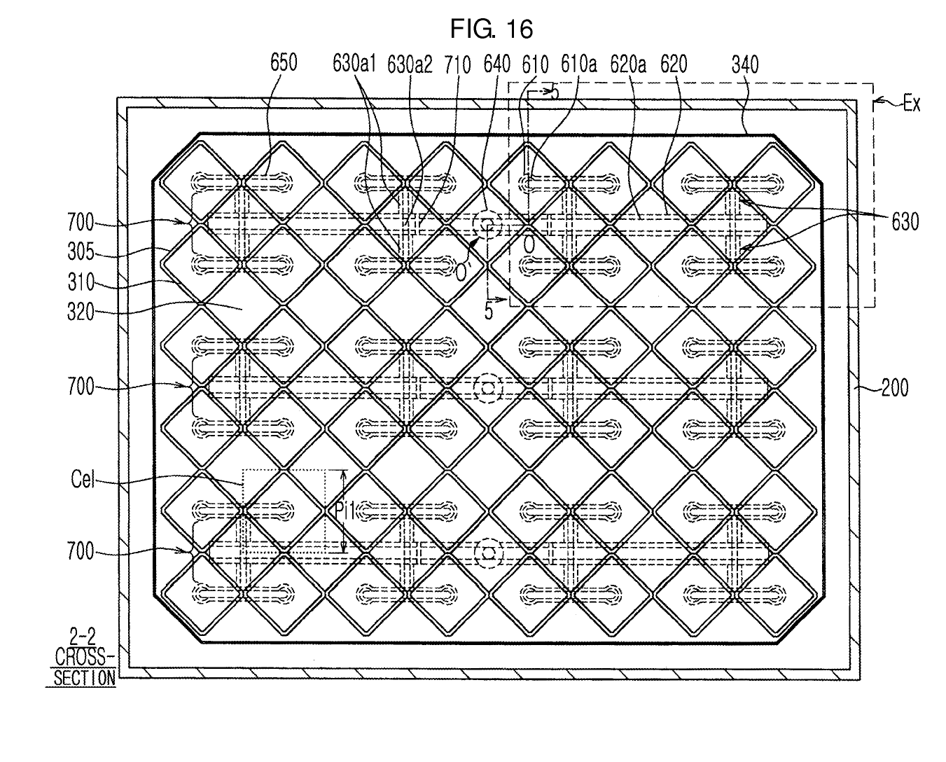

A structure of the microwave plasma processing apparatus according to a fifth embodiment of the present invention will now be explained with reference to FIG. 16. FIG. 16 shows a ceiling surface of the microwave plasma processing apparatus according to the present embodiment. Since a cross-sectional view taken along line 5-0-0′-5 of FIG. 16 is the same as the cross-sectional view taken along line 1-0-0′-1 described in the first embodiment (FIG. 2) and an enlarged view of an area Ex of FIG. 16 is the same as the area Ex of FIG. 1 described in the first embodiment (FIG. 3), the outline of the microwave plasma processing apparatus will not be explained.

The fifth embodiment is different from the first embodiment in that each of the third coaxial waveguides 630 is perpendicularly connected to the second coaxial waveguide 620 in the fifth embodiment whereas each of the third coaxial waveguides 630 has a portion that extends non-perpendicularly with respect to the second coaxial waveguide 620 in the first embodiment.

### (Principle of Impedance Matching of Coaxial Waveguide Branch Structure)

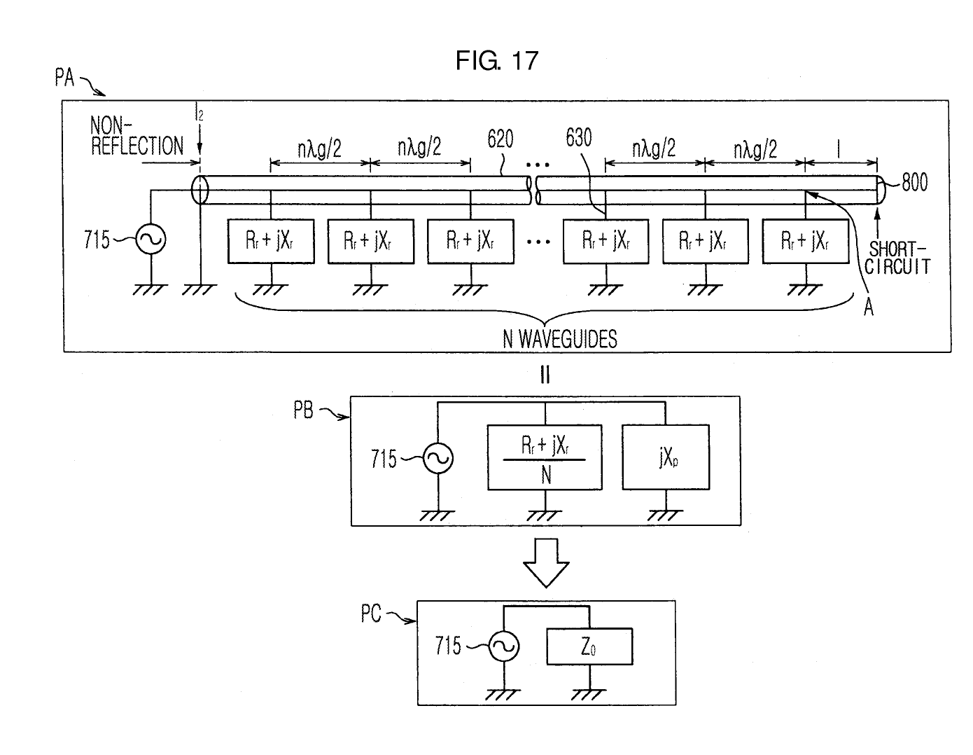

The principle of impedance matching of a coaxial waveguide branch structure according to the present embodiment will now be explained with reference to FIG. 17. The assumed coaxial waveguide branch structure, as shown in PA of FIG. 17, is multi-branched to N (N≦3) third coaxial waveguides 630 from the second coaxial waveguide 620. A pitch between adjacent third coaxial waveguides 630 is an integer multiple of λg/2, and a distance between a short-circuited surface of an end portion of the second coaxial waveguide 620 and a branched portion A closet to the end portion (a connected portion between the second coaxial waveguide 620 and each of the third coaxial waveguides 630) is determined to be a length l due to a short-circuit plate 800.

An impedance obtained by observing a third coaxial waveguide side from the connected portion is denoted by Rᵣ+jXᵣ (Rᵣ is referred to as a load resistance and Xᵣ is referred to as a load reactance).

Here, it is assumed that electromagnetic waves applied from the electromagnetic wave source 715 to the second coaxial waveguide 620 are transmitted to the second coaxial waveguide 620 and the third coaxial waveguides 630 without loss. The N third coaxial waveguides 630 when a pitch between the third coaxial waveguides 630 is an integer multiple of λg/2 are equivalent to the N third coaxial waveguides being connected in parallel. Accordingly, the circuit of PA of FIG. 17, as shown in PB of FIG. 17, is equivalent to a circuit where (Rᵣ+jXᵣ)/N and a reflectance ; (Xₚ (Xₚ is referred to as a plunger reactance) obtained by observing an end portion side from the connected portion A are connected in parallel to the electromagnetic wave source 715.

Here, the plunger reactance is expressed as Equation 1.

Xₚ=Z₀tan(2πl/λg) (1)

where Z₀ is a characteristic impedance of a coaxial waveguide.

In this equivalent circuit, conditions under which there is no reflection in an incident end l₂ of the second coaxial waveguide 620 is when an imaginary part and a real part of an impedance when observing from the incident end 12 are respectively 0 and Z₀, that is, when the equivalent circuit shown in PC of FIG. 17 is established.

When Z₀>Rᵣ/N, conditions for no reflection are represented by following Equations 2 and 3.

Xᵣ²=Rᵣ(N×Z₀−Rᵣ) (2)

Xₚ=−Xᵣ×Z₀/(N×Z₀−Rᵣ) (3)

In order to satisfy Equations 2 and 3, reactance components (Xᵣ, Xₚ) need to be adjusted in accordance with the resistance Rᵣ of the third coaxial waveguides 630. Hereinafter, impedance matching that satisfies the conditions of Equations 2 and 3 is referred to as impedance matching of a capacitively coupled type.

In the capacitively coupled-type impedance matching, the reactance components Xᵣ, Xₚ are obtained based on Equations 2 and 3 which are the conditions for no reflection with respect to a desired load resistance Rᵣ (which is the same as a characteristic impedance of the third coaxial waveguides when an output side from the third coaxial waveguides is matched). For example, as the reactance component Xᵣ, a dielectric coupling may be interposed between inner conductors of a connected portion as a dielectric member having a specific capacity component 1/ωXᵣ (ω is an angular frequency of an electromagnetic wave). Also, a length l of a plunger may be determined to be the reactance component Xₚ from Equation 1.

When Z₀=Rᵣ/N, conditions for no reflection are represented by following Equations 4 and 5.

Xᵣ=0 (4)

Xₚ=∞ (5)

In order to satisfy Equation 4, a reactance component of the inner conductor 630a of each of the third coaxial waveguides is 0. Also, in order to satisfy Equation 5, from Equation 1, a relationship that l is an odd multiple of (λg/4) needs to be satisfied. That is, it is preferable that an electrical length of the plunger is an odd multiple of π/2 rad. Hereinafter, impedance matching that satisfies the conditions of Equations 4 and 5 is referred to as impedance transformation-type impedance matching.

In order to satisfy conditions of Z₀=Rᵣ/N, a load resistance Rᵣ needs to be pretty high. Accordingly, for example, the third coaxial waveguides function as an impedance transformation unit having an electrical length of π/2 rad. If there is no reactance component, arbitrary impedance transformation can be made by changing a characteristic impedance of the third coaxial waveguides.

### (Multi-Branch Structure: Symmetric 8-Branch Structure)

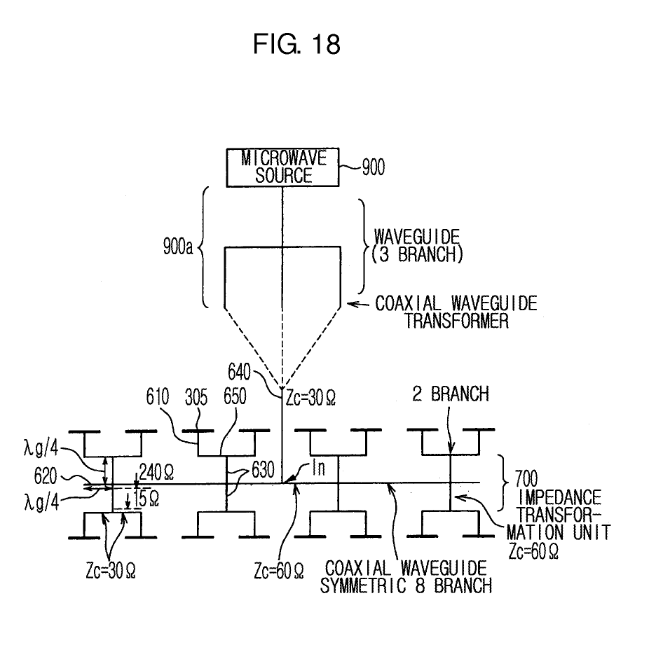

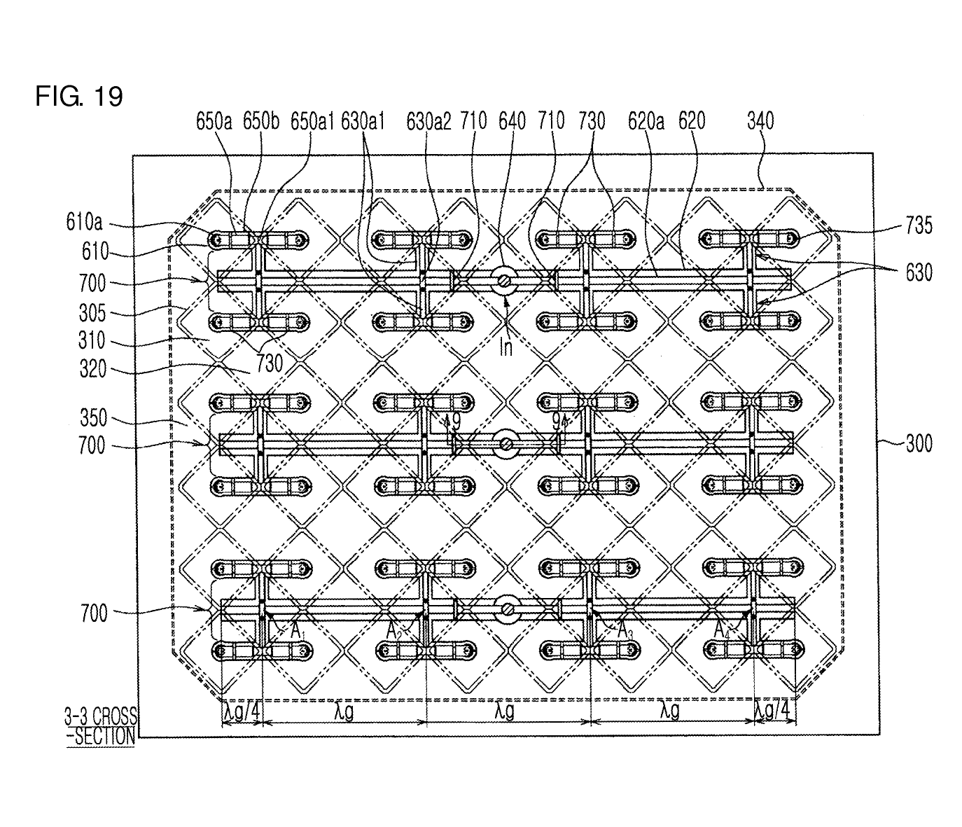

A multi-branch structure (a symmetric 8-branch structure) according to the present invention will now be explained with reference to FIGS. 18 and 19. FIG. 18 is a schematic view of a branch circuit including the coaxial waveguide distributor 700. FIG. 19 is a cross-sectional view of the lid according to the present embodiment taken along line 3-3 of FIG. 2. Here, impedance transformation-type impedance matching is performed (by an impedance transformation unit of FIG. 18).

The microwave source 900 is connected to the waveguide, is 3-branched, and transmits microwaves to the fourth coaxial waveguide 640 through the coaxial waveguide transformer. The fourth coaxial waveguide 640 is 2-branched (T-branched) to be connected to the second coaxial waveguide 620. A portion of the second coaxial waveguide 620 on which microwaves are incident from the fourth coaxial waveguide 640 is referred to as the input portion In of the second coaxial waveguide 620 hereinafter. The coaxial waveguide distributor 700 has a multi-branch structure including the second coaxial waveguide 620 having the input portion In and the third coaxial waveguides 630 that are connected at 4 places to the second coaxial waveguide 620 and extend substantially perpendicular to the second coaxial waveguide 620. 2 of the third coaxial waveguides 630 are connected to the second coaxial waveguide 620 at a connected portion between the second coaxial waveguide 620 and each of the third coaxial waveguides 630. In the present embodiment, 8 of the third coaxial waveguides 630 are connected to the second coaxial waveguide 620. Each of 8 of the third coaxial waveguides 630 is T-branched to the fifth coaxial waveguide 650, both end portions of the fifth coaxial waveguide 650 are connected to the first coaxial waveguides 610, and terminal ends of the first coaxial waveguides 610 are connected to the dielectric plates 305.

Accordingly, microwaves of 915 MHz output from one microwave source 900 pass through an isolator, a directional coupler, a matcher (not shown), a waveguide 3-distributor, and 3 coaxial waveguide transformers, are transmitted through the fourth coaxial waveguide 640, and are transmitted while power is equally distributed due to the coaxial waveguide distributor 700 including the second coaxial waveguide 620 and 8 of the third coaxial waveguides 630. The microwaves transmitted to the third coaxial waveguides 630 are transmitted to the dielectric plates 305 through the fifth coaxial waveguides 650 and the first coaxial waveguides 610, and are emitted into the processing container from the dielectric plates 305 exposed from the peripheries of the metal electrodes 310. In the present apparatus, 3 of the second coaxial waveguides 620 are arranged at regular pitches in parallel to one another.

Although 8 of the third coaxial waveguides 630 are connected to the second coaxial waveguide 620 in the present embodiment, 3 or more of the third coaxial waveguides 630 may be connected to the second coaxial waveguide 620. A branched portion formed in the coaxial waveguide distributor 700 according to the present embodiment has a symmetric multi-branch structure. The term “symmetric multi-branch structure” refers to a structure where the number and connected positions of the third coaxial waveguides 630 connected to the end of one branch from the input portion In at the center of the inner conductor of the second coaxial waveguide and the number and connected positions of the third coaxial waveguides 630 connected to the end of another branch from the input portion In at the center of the inner conductor of the second coaxial waveguide are the same, and thus 3 or more branches are symmetric about the input portion In.

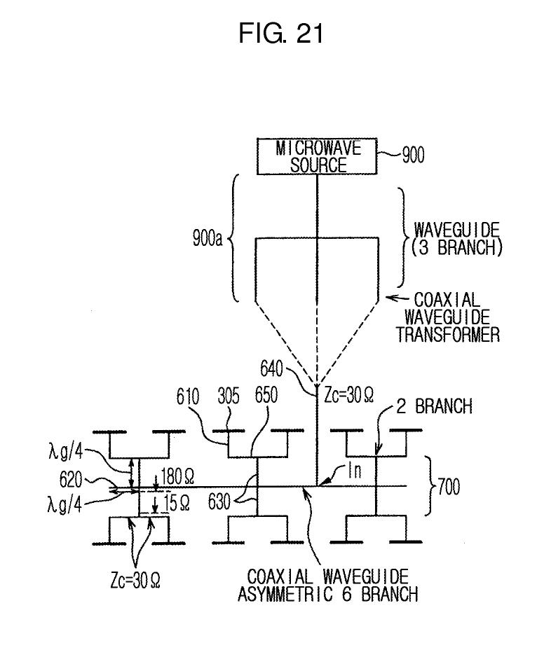

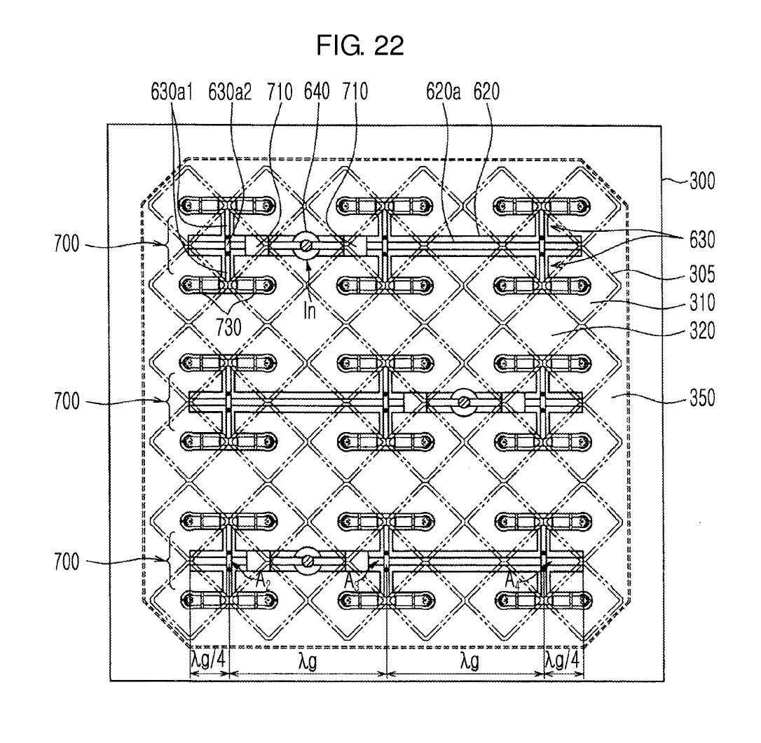

Meanwhile, the branched portion formed in the coaxial waveguide distributor 700 according to a sixth embodiment which will be explained later has an asymmetric multi-branch structure. The term “asymmetric multi-branch structure” refers to, as shown in, for example, FIGS. 21 and 22, a structure where the number and connected positions of the third coaxial waveguides 630 connected to the end of one branch from the input portion In at the center of the inner conductor of the second coaxial waveguide and the number and connected positions of the third coaxial waveguides 630 connected to the end of another branch from the input portion In at the center of the inner conductor of the second coaxial waveguide are not the same, and thus 3 or more branches are not symmetric about the input portion In.

As shown in FIG. 19, from among connected portions A₁ through A₄ between the inner conductor 620a and the inner conductor 630a, the input portion In is a center point between the connected portion A₂ and the connected portion A₃. When guide wavelengths of the second coaxial waveguide 620 are λg₂, a pitch of the third coaxial waveguides 630 (a distance between connected portions) is substantially equal to an integer multiple (1 time in the present embodiment) of λg₂. Accordingly, power can be equally distributed to the third coaxial waveguides 630 from the second coaxial waveguide 620.

More accurately, when an electrical length between the connected portion A₁ and the connected portion A₂ and an electrical length between the connected portion A₃ and the connected portion A₄ between the inner conductor 620a of the second coaxial waveguide and the inner conductor 630a of each of the third coaxial waveguides are integer multiples of π rad, amplitudes of microwaves to be transmitted to all of the third coaxial waveguides 630 are the same. Also, when such electrical lengths are odd multiples of π rad, a difference between phases of microwaves to be transmitted to the connected portion A₁ of the third coaxial waveguides 630, the connected portion A₂ of the third coaxial waveguides 630, the connected portion A₃ of the third coaxial waveguides 630, and the connected portion A₄ of the third coaxial waveguides 630 is π rad. Meanwhile, when such electrical lengths are even multiples of π rad, that is, integer multiples of 2π rad, phases of microwaves to be transmitted to all of the third coaxial waveguides 630 are the same. In the present embodiment, since microwaves should be in phase, it is preferable that such electrical lengths are integer multiples of 2π rad.

In order to arrange cells at regular pitches, a distance between the connected portion A₂ and the connected portion A₃ is Ag₂ which is equal to a distance between the connected portion A₁ and the connected portion A₂. Also, since a propagation mode (TEM mode) is collapsed around connected portions, an electrical length is changed. Accordingly, actually, a pitch of the third coaxial waveguides 630 is set to be several mm longer than guide wavelengths λg₂ (=327.6 mm) of the second coaxial waveguide.

A structure of the coaxial waveguide distributor 700 will be explained in more detail with reference to FIG. 19. The center of the second coaxial waveguide 620 is connected to the fourth coaxial waveguide 640. From the input portion In of the second coaxial waveguide 620 to end portions of the second coaxial waveguide 620, 2 of the third coaxial waveguides 630 are substantially perpendicularly connected to each end portion of the second coaxial waveguide. It is preferable that the number of the third coaxial waveguides 630 connected to a space between the input portion In of the second coaxial waveguide 620 and an end portion of the second coaxial waveguide 620 is 2 or less. This is because although the frequency of microwaves is changed, the balance of power shared by the third coaxial waveguides 630 is hard to be broken.

The inner conductor 620a and the outer conductor 620b of the second coaxial waveguide are short-circuited at both ends of the second coaxial waveguide 620, and an electrical length in a space between an end portion of the second coaxial waveguide 620 and a connected portion between the second coaxial waveguide 620 and the third coaxial waveguides 630 closest to the end portion is substantially equal to an odd multiple (here, 1 time) of π/2 rad. Accordingly, this space may be regarded as a distributed line having one end short-circuited. In this regard, in the case of a distributed line having an electrical length of π/2 rad with one end short-circuited, an impedance observed from the one end appears to be infinite. Accordingly, in the transmission of microwaves, since there seems no portion between the end portion of the second coaxial waveguide 620 and the connected portion, a transmission line can be easily designed.

The fifth coaxial waveguide 650 is connected to an output end of the inner conductor 630a (the rod 630a1) and is T-branched. The first coaxial waveguides 610 are perpendicularly connected to both end portions of the fifth coaxial waveguide 650 toward the inside of the drawing sheet. Due to this configuration, microwaves are input from the input portion In of the second coaxial waveguide 620 to the coaxial waveguide distributor 700, are transmitted through the second coaxial waveguide 620, are multi-branched and distributed to the third coaxial waveguides 630, pass through the fifth coaxial waveguide 650 and the first coaxial waveguides 610, and are emitted from adjacent plurality of dielectric plates 305 into the processing container.

### (Fourth Coaxial Waveguide and T-Branching)

A connected portion between the fourth coaxial waveguide 640 and the second coaxial waveguide 620 which is shown in the cross-sectional view taken along line 9-9 of FIG. 19 is the same in terms of configuration as a connected portion of each coaxial waveguide of the microwave plasma processing apparatus shown in the cross-sectional view taken along line 4-4 of FIG. 5 (that is, FIG. 6) according to the first embodiment, and the connected portion between the fourth coaxial waveguide 640 and the second coaxial waveguide 620 is 2-branched (T-branched) in a T-like shape.

### (Fifth Coaxial Waveguide and T-Branching)

A T-branch structure by the third and fifth coaxial waveguides 630 and 650 will now be explained with reference to FIG. 19. The third coaxial waveguides 630 are substantially perpendicularly connected to the second coaxial waveguide 620 and the fifth coaxial waveguides 650. The inner conductor 650a of the fifth coaxial waveguides is formed of copper like the inner conductors 620a and 630a of the second and third coaxial waveguides. A connected portion between the inner conductors 630a and 650a of the third and fifth coaxial waveguides is fixed by soldering or brazing in a state where the inner conductor 630a of each of the third coaxial waveguides is inserted into a recess portion of the inner conductor 650a of the fifth coaxial waveguide.

Grooves are formed at both sides of the T-branch structure in an outer circumferential portion of the inner conductor 650a of the fifth coaxial waveguides 650, and the dielectric rings 730 are inserted into the grooves. Accordingly, the inner conductor 650a of the fifth coaxial waveguide is supported to the outer conductor 650b. The inner conductor 650a of the fifth coaxial waveguides 650 is also supported from side portions by the dielectric rods 735. The dielectric rods 735 are inserted into holes formed in the inner conductor 650a of the fifth coaxial waveguides and fix the inner conductor 610a of each of the first coaxial waveguides 610 to the fifth coaxial waveguide 650. The dielectric rings 730 and the dielectric rods 735 are formed of Teflon.

### (Impedance Transformation Mechanism)

An impedance transformation mechanism of a coaxial waveguide will now be explained in an order of an impedance transformation type and a capacitively coupled type.

### (Impedance Matching of Impedance Transformation Type)

As described above, in order to remove reflection in the coaxial waveguide distributor 700, an impedance obtained by observing a third coaxial waveguide side from a connected portion between the second coaxial waveguide 620 and the third coaxial waveguides 630 may be a desired real number. When an output side of the third coaxial waveguides 630 is matched, an impedance obtained by observing the third coaxial waveguide side from the connected portion may be a real number by designing that an electrical length of the third coaxial waveguides 630 is substantially π/2 rad. Also, an impedance obtained by observing the third coaxial side from the connected portion may be a desired value by changing a characteristic impedance of the third coaxial waveguides.

In the inner conductor 630a of each of the aforesaid third coaxial waveguides, a portion connected with the inner conductor 620a of the second coaxial waveguide (the inner conductor connection plate 630a2) is narrower than another portion (the rod 630a1). As such, an electrical length of the third coaxial waveguides 630 may be lengthened by narrowing the inner conductor 630a of each of the third coaxial waveguides.

Also, although not shown, an electrical length of each of the third coaxial waveguides 630 may be lengthened by narrowing a connected portion between the inner conductor 630a of each of the third coaxial waveguides and the inner conductor 650 of the fifth coaxial waveguides or thickening the outer conductor 630b.

Also, an electrical length of each of the third coaxial waveguides 630 may be lengthened by narrowing a connected portion between the inner conductor 650a of the fifth coaxial waveguides and the inner conductor 630a of each of the third coaxial waveguides like the narrowed portion 650a1 of FIG. 19, or thickening the outer conductor 650b.

As described above, an electrical length of the third coaxial waveguides can be adjusted by forming a narrowed portion or a thickened portion in each of the third coaxial waveguides 630 and adjusting a length or a thickness of the narrowed portion or the thickened portion of each of the third coaxial waveguides 630. Also, an electrical length of a coaxial waveguide (here, the second or fifth coaxial waveguide) connected to each of the third coaxial waveguides may be adjusted by adjusting a length or a thickness of the coaxial waveguide connected to each of the third coaxial waveguides. Due to such adjustment means (impedance transformation mechanism), a cell pitch Pi1 (refer to FIG. 16) in a direction perpendicular to the second coaxial waveguide 620 can be relatively freely determined.

### (Impedance Buffer Portion)

As an inner conductor is thickened, an impedance is decreased, and as an inner conductor is narrowed, a characteristic impedance is increased. Accordingly, if the inner conductor 630a of each of the third coaxial waveguides and the inner conductor 650a of the fifth coaxial waveguides which have different thicknesses are directly connected to each other, since a characteristic impedance is greatly changed, reflection at a connected portion is increased. Accordingly, the narrowed portion 650a1 of the connected portion between the inner conductor 650a of the fifth coaxial waveguides and the inner conductor 630a of each of the third coaxial waveguides functions to reduce reflection. As such, since the narrowed portion 650a1 functions as an impedance buffer portion and can connect the inner conductor 630a of the third coaxial waveguides and the inner conductor 650a of the fifth coaxial waveguide while slowly gradually changing a characteristic impedance, the reflection of microwaves is suppressed, and thus microwaves can be easily introduced into the left and the right of the fifth coaxial waveguides 650.

In the case of a symmetric multi-branch structure, impedances obtained by observing both ends from the input portion In of the second coaxial waveguide 620 can be respectively matched, and an impedance obtained by observing a load side from the fourth coaxial waveguide 640 can be matched. As a result, since there is no reflection when observing from an input side of the coaxial waveguide distributor 700, microwaves of large power can be transmitted. When the following conditions are satisfied, an impedance obtained by observing a load side from the second coaxial waveguide 620 can be matched.

That is, when an impedance obtained by observing a plasma side from the first coaxial waveguides 610 is matched, an impedance obtained by observing an output side from an output end of the third coaxial waveguides 630 is substantially resistive, and when a resistance obtained by observing the output side from the output end of the third coaxial waveguides 630 is Rᵣ₅, the number of the third coaxial waveguides 630 connected to a space between the input portion In of the second coaxial waveguide 620 and an end portion of the second coaxial waveguide 620 is Nₛ, and a characteristic impedance of the second coaxial waveguide 620 is Z_{c2}, a characteristic impedance Z_{c3} of the third coaxial waveguides 630 is substantially equal to (Rᵣ₅×Nₛ×Z_{c2})^{1/2} and an electrical length of the third coaxial waveguides 630 is π/2 rad. For example, in the case of the 8-branch structure shown in FIG. 18, since 2 of the fifth coaxial waveguides 650 having a characteristic impedance of 30 Ω are connected in parallel to an output end of each of the third coaxial waveguides 30, Rᵣ₅=15 Ω. Also, when Nₛ=4 and Z_{c2}=60 Ω, Z_{c3} may be 60 Ω.

Also, when an impedance obtained by observing a third coaxial side from a connected portion between the second coaxial waveguide 620 and each of the third coaxial waveguides 630 is substantially resistive, a resistance obtained by observing the third coaxial waveguide side from the connected portion between the second coaxial waveguide 620 and each of the third coaxial waveguides 630 is Rᵣ₃, the number of the third coaxial waveguides 630 connected to a space between the input portion In of the second coaxial waveguide 620 and one end of the second coaxial waveguide 620 is Nₛ, and a characteristic impedance of the second coaxial waveguide 620 is Z_{c2}, the characteristic impedance Z_{c2} of the second coaxial waveguide 620 is substantially equal to Rᵣ₃/Nₛ.

For example, in the case of the 8-branch structure shown in FIG. 18, since Rᵣ₃=240 and Z_{c2}=240/4=60 Ω, the above relationship is satisfied.

### (Impedance Matching of Capacitively Coupled Type)

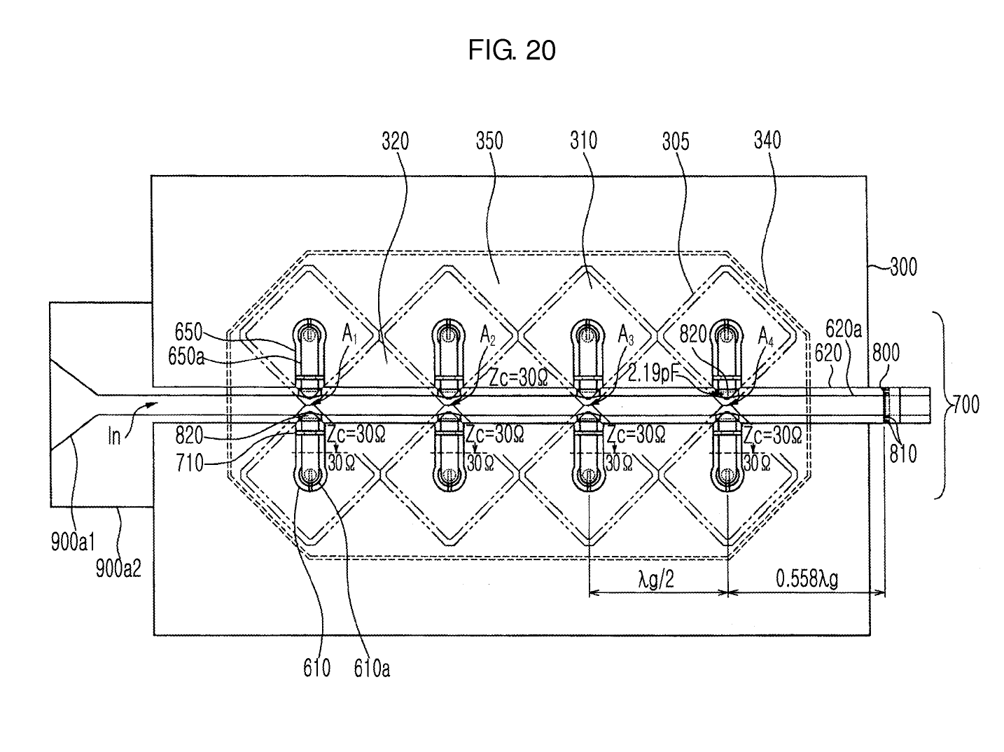

Impedance matching of a capacitively coupled type will now be explained with reference to FIG. 20. In the capacitively coupled type, a dielectric member is disposed at a connected portion of a coaxial waveguide which is multi-branched. In FIG. 20, each of dielectric couplings 820 is disposed at a connected portion with the inner conductor 620a of the second coaxial waveguide. The dielectric couplings 820, which are an example of an impedance transformation mechanism for adjusting an impedance, correspond to dielectric members disposed at the connected portions with the second coaxial waveguide 620. In the present embodiment, the dielectric couplings 820 are formed of Teflon.

In FIG. 20, by means of the dielectric couplings 820, the inner conductor 620a of the second coaxial waveguide 620 and the inner conductor 650a of the fifth coaxial waveguides are connected, and one end of each of the fifth coaxial waveguide 650 is connected to each of the first coaxial waveguides 610. In this embodiment, the third coaxial waveguides 630 shown in FIG. 16 do not exist. Also, there is no T-branching. Accordingly, in ┌the second coaxial waveguide and 3 or more of the third coaxial waveguides substantially perpendicularly connected to the second coaxial waveguide which are included in the coaxial waveguide distributor 700┘, ┌the second coaxial waveguide┘ refers to a coaxial waveguide from which branching is performed (here, the second coaxial waveguide 620), and the third coaxial waveguides refer to coaxial waveguides at an end of a branch (here, the fifth coaxial waveguides 650).

In FIG. 20, 8 of the fifth coaxial waveguides 650 having a characteristic impedance of 30 Ω are substantially perpendicularly connected to the second coaxial waveguide 620 having a characteristic impedance of 30 Ω at regular pitches. In this case, from Equation 2, a load reactance Xᵣ is calculated to be −79.4 Ω which corresponds to a capacity of 2.19 pF at 915 MHz. A capacity of the dielectric couplings 820 is designed to be this value. Likewise, from Equation 3, a plunger reactance Xₚ is calculated to be 11.3 Ω. Also, since a length l of a plunger (a distance between an end portion of the second coaxial waveguide 620 and a connected portion closest to the end portion) calculated from Equation 1 is 0.558 λg₂, a position of the short-circuit plate 800 is adjusted. The short-circuit plate 800 is slidably fixed to the second coaxial waveguide 620 by the shield spiral 810.

An end portion at a non-short-circuited side of the second coaxial waveguide 620 is connected to a coaxial waveguide transformer 900a1. The coaxial waveguide transformer 900a1 is disposed to be adhered to a sidewall of the lid 300, and is connected to a waveguide 900a2 that is disposed in a direction perpendicular to the drawing sheet (vertical direction of the apparatus). Microwaves are fed by using one end of the second coaxial waveguide as the input portion In through the waveguide 900a2 and the coaxial waveguide transformer 900a1.

A pitch between fifth coaxial waveguides is λg₂/2. Accordingly, a difference between phases of microwaves to be transmitted to adjacent fifth coaxial waveguides 650 is π rad.

Even in the capacitively coupled type, in the case of a symmetric multi-branch structure, impedances obtained by observing both ends from the input portion In of the second coaxial waveguide 620 can be respectively matched, and an impedance obtained by observing a load side from the fourth coaxial waveguide 640 can be matched. As a result, since there is no reflection when observing from an input side of the coaxial waveguide distributor 700, microwaves having large power can be transmitted.

Also, in the symmetric multi-branch structure, a transmission path does not need to be designed in such a manner that antinodes of microwaves are located at the input portion In of the second coaxial waveguide 620. Since a characteristic impedance is matched in such a manner that there is almost no reflection when an output side is observed from an output end (the input portion In) of the inner conductor 620a of the second coaxial waveguide and no reflection is generated when the left and the right are observed from the dielectric rings 705 existing at both sides of the input portion In, standing waves do not arise in the second coaxial waveguide 620. Accordingly, a length or a shape of each of the third coaxial waveguides 630 can be freely designed without being restricted by guide wavelengths Ag of microwaves.

### Embodiment 6

### (Asymmetric 6-Branch Structure)

A branch circuit of a G4.5 glass substrate according to a sixth embodiment will now be explained with reference to FIGS. 21 and 22. FIG. 21 is a schematic view of a branch circuit including the coaxial waveguide distributor 700 according to the present embodiment. FIG. 22 shows a ceiling surface of the microwave plasma processing apparatus 10 according to the present embodiment. The present embodiment has a multi-branch structure in which a coaxial waveguide is 6-branched in an asymmetric manner. The size of the G.4.5 glass substrate is 730×920 mm. An impedance transformation mechanism is the aforesaid impedance transformation type.

In the present embodiment, as shown in FIG. 21, the transmission line 900a includes a waveguide, a coaxial waveguide transformer, and a plurality of coaxial waveguides. Microwaves output from one microwave source 900 are 3-branched at the waveguide, are transmitted to the coaxial waveguide transformer, and are transmitted to the coaxial waveguide distributor 700 through the fourth coaxial waveguide 640. The coaxial waveguide distributor 700 has a multi-branch structure including the third coaxial waveguides 630 that are 6-branched in an asymmetric manner from the second coaxial waveguide 620 having the input portion In.

As shown in FIG. 22, 36 cells in total are uniformly arranged in such a manner that 6 cells are arranged in a substrate longer direction and in a substrate shorter direction. The input portion In is located at a center point between the connected A₂ and the connected portion A₃ or a center point between the connected portion A₃ and the connected portion A₄. As described above, in the case of a symmetric multi-branch structure, impedances obtained by observing both ends from the input portion In of the second coaxial waveguide 620 can be respectively matched and an impedance obtained by observing a load side from the fourth coaxial waveguide 640 can be also matched.

However, in the case of an asymmetric multi-branch structure, if impedances obtained by observing both ends from the input portion In of the second coaxial waveguide 620 are respectively matched, since power of microwaves transmitted to the left and the right becomes the same, power of microwaves supplied to cells in the left becomes different from power of microwaves supplied to cells in the right. Accordingly, impedances obtained by observing both ends from the input portion In of the second coaxial waveguide 620 cannot be matched. However, if the following conditions are satisfied, an impedance obtained by observing a load side from the fourth coaxial waveguide 640 can be matched. As a result, microwaves of large power can be transmitted.

That is, when the fourth coaxial waveguide 640 having a characteristic impedance Z_{c4} is connected to the input portion In of the second coaxial waveguide 620 and an impedance obtained by observing a plasma side from the first coaxial waveguides 610 is matched, an impedance obtained by observing an output side from an output end of the third coaxial waveguides 630 is substantially resistive, and when an resistance obtained by observing the output side from the output end of the third coaxial waveguides 630 is Rᵣ₅ and the number of the third coaxial waveguides 630 connected to the second coaxial waveguide 620 is Nₜ, a characteristic impedance Z_{c3} of the third coaxial waveguides 630 is substantially equal to (Rᵣ₅×Nₜ×Z_{c4})^{1/2} and an electrical length of the third coaxial waveguides 630 is π/2 rad. For example, in the case of a 6-branch structure shown in FIG. 21, since 2 fifth coaxial waveguides 650 having a characteristic impedance of 30 Ω are connected in parallel to the output end of each of the third coaxial waveguides 630, Rᵣ₅=15 Ω. Also, when Nₜ=6 and Z_{c4}=30 Ω, Z_{c3} may be 52 Ω.

Also, when an impedance obtained by observing a third coaxial side from a connected portion between the second coaxial waveguide 620 and each of the third coaxial waveguides 630 is substantially resistive, a resistance obtained by observing the third coaxial waveguide side from the connected portion is Rᵣ₃, and the number of the third coaxial waveguides 630 connected to the second coaxial waveguide 620 is Nₜ, a characteristic impedance Z_{c4} is substantially equal to Rᵣ₃/Nₜ.

When an impedance obtained by observing a plasma side from the first coaxial waveguides 610 is matched, an impedance obtained by observing a third coaxial waveguide side from a connected portion between the second coaxial waveguide 620 and each of the third coaxial waveguides 630 is substantially resistive and, when a resistance obtained by observing the third coaxial waveguide side from the connected portion is Rᵣ₃, the number of the third coaxial waveguides 630 connected to a space between the input portion In of the second coaxial waveguide 620 and an one end of the second coaxial waveguide 620 is Nₛ, and a characteristic impedance of the second coaxial waveguide 620 is Z_{c2}, the characteristic impedance Z₂ of the second coaxial waveguide 620 is substantially equal to Rᵣ₃/Nₛ.

For example, in the case of the 6-branch structure shown in FIG. 21, since Rᵣ₃=180 and Z_{c4}=180/6=30 Ω, the above relationship is satisfied.

In the case of a symmetric multi-branch structure, since impedances obtained by observing both ends from the input portion In of the second coaxial waveguide 620 can be matched and thus standing waves do not arise at the connected portions A₂ through A₃, an interval between the connected portions A₂ through A₃ is arbitrary. Meanwhile, in the case of an asymmetric branch structure, since standing waves arise at the connected portions A₂ through A₃, an electrical length between the connected portions A₂ through A₃ must be an integer multiple (1 time in the present embodiment) of 2π rad.

However, if a coaxial waveguide is connected to an input portion In, since a propagation mode is collapsed around a connected portion, an electrical length is changed. In order to correct the change in the electrical length, the dielectric rings 710 formed of Teflon are disposed between the input portion In and the connected portion A₂ and between the input portion In and the connected portion A₃. By optimizing thicknesses, positions, and permittivity of the dielectric rings 710, even in the asymmetric multi-branch structure, microwaves having desired amplitude and phase can be transmitted to an end of a branch.

Also, although only the impedance transformation type is explained in the aforesaid asymmetric multi-branch structure, the capacitively coupled type can also be used. In this case, when the fourth coaxial waveguide 640 having a characteristic impedance Z_{c4} is connected to the input portion In of the second coaxial waveguide 620, the number of the third coaxial waveguides 630 connected to the second coaxial waveguide 620 is Nₜ, and a characteristic impedance of the third coaxial waveguides 630 is Z_{c3}, a relationship Z₃ <Nₜ×Z_{c4} is satisfied, a reactance Xᵣ of the dielectric couplings 820 is substantially equal to −(Z_{c3}(Nₜ×Z_{c4}−Z_{c3}))^{1/2}, and a reactance Xₚ obtained by observing an end portion side of the second coaxial waveguide 620 from a connected portion between the second coaxial waveguide 620 and the third coaxial waveguides 630 closest to the end portion is substantially equal to −2Xᵣ×Z_{c4}/(Nₜ×Z_{c4}−Z_{c3}).

### (Modified Example of Sixth Embodiment)

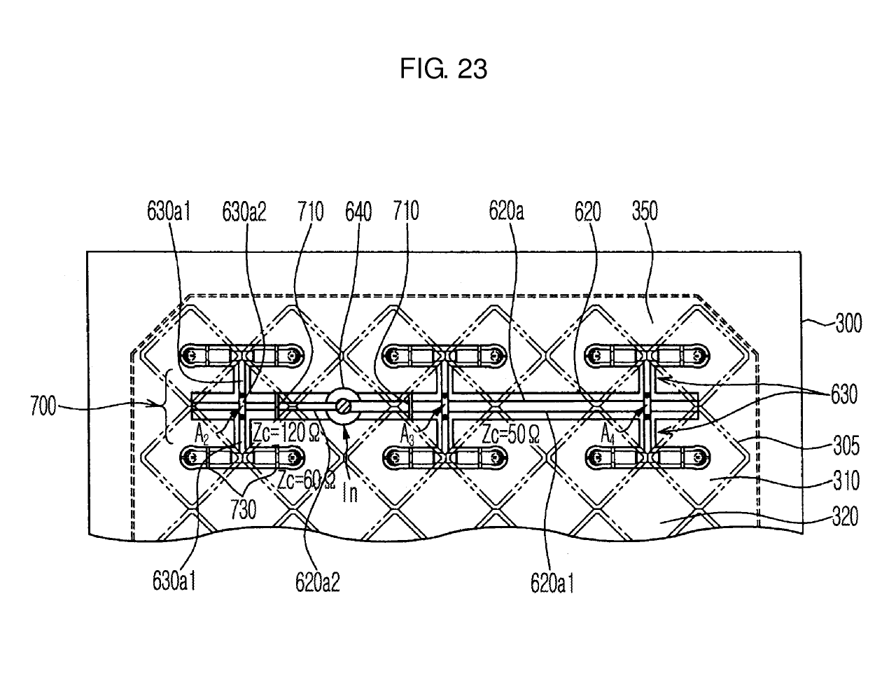

FIG. 23 shows a modified example of the sixth embodiment. In the present modified example, despite an asymmetric multi-branch structure, impedances obtained by observing both ends from the input portion In of the second coaxial waveguide 620 are matched. 4 of the third coaxial waveguides 630 and 2 of the third coaxial waveguides 630 are respectively connected to the right and the left of the input portion In of the second coaxial waveguide 620. Accordingly, in order to equally supply microwave power to all cells, power supplied to the right may be 2 times higher than power supplied to the left. Accordingly, by making an inner conductor 620a2 at the left of the second coaxial waveguide narrower than an inner conductor 620a1 at the right of the second coaxial waveguide, a characteristic impedance (120 Ω) at the left side is set to be 2 times higher than a characteristic impedance (60 Ω) at the right side. Also, in order that impedances obtained by observing both ends from the input portion In are matched, a characteristic impedance (all 60 Ω) of the third coaxial waveguides is optimized based on the aforesaid matching conditions. According to the present modified example, since an electrical length between the connected portions A₂ through A₃ by using the dielectric rings or the like does not need to be adjusted, the design can be facilitated.

### Embodiment 7

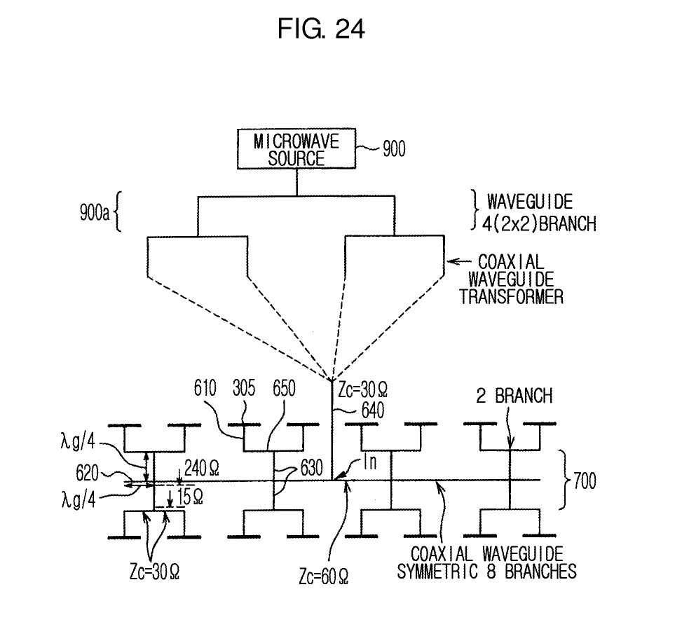

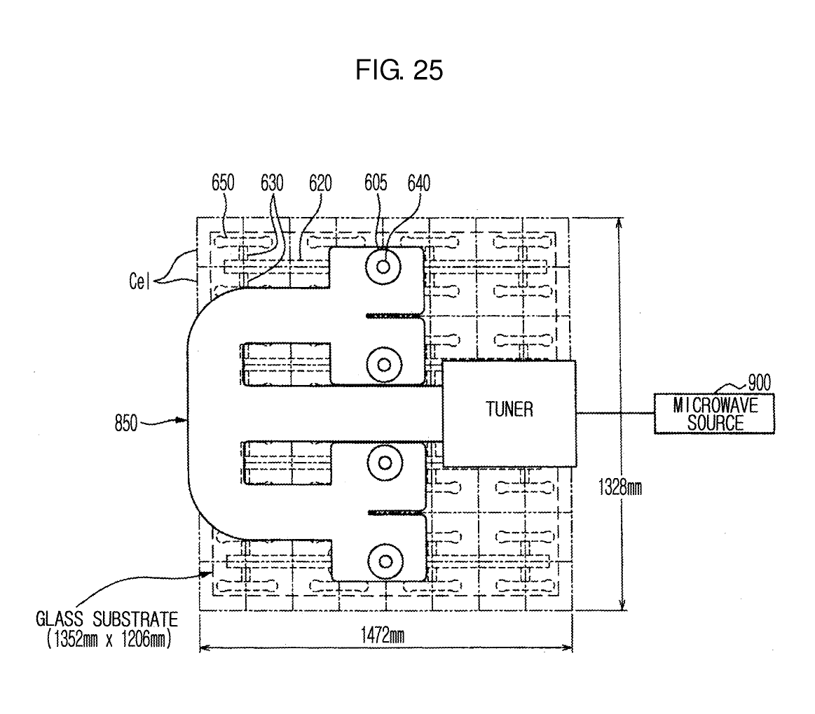

A branch circuit of a solar cell glass substrate according to a seventh embodiment will now be explained with reference to FIGS. 24 and 25. FIG. 24 is a schematic view of a branch circuit including the coaxial waveguide distributor 700. FIG. 25 shows the waveguide distributor 850 held on the microwave plasma processing apparatus. In the present embodiment, multi-branch structure is used where waveguides is 8-branched in a symmetric manner. An impedance transformation mechanism is the aforesaid impedance transformation-type impedance transformation mechanism.

The waveguide distributor 850 has a plane shape and is 2×2-branched in a tournament manner. The waveguide is branched in a symmetric manner at both sides from the microwave source 900 and a tuner. Since the waveguide distributor 850 has a plane shape, the waveguide is thin (in a direction perpendicular to the drawing sheet of FIG. 25) and the waveguide can be easily held on the apparatus.

64 cells in total are uniformly arranged in such a manner that 8 cells are arranged in a substrate longer direction and a substrate shorter direction. Coaxial waveguide symmetric 8 branches are installed in 1 row and 4 columns. The size of a cell is optimized in such a manner that the coaxial waveguide distributor 700 has a simplest structure. That is, the cell has a length of 166 mm in a horizontal direction and a length of 184 mm in a vertical direction. From this, a size of a plasma excitation area is approximately 1328×1472 mm. Considering processing uniformity, the plasma excitation area needs to be larger than a substrate. In the present embodiment, the size of a most practical glass substrate is 1206×1352 mm. Since the substrate size allows one person alone to carry the substrate, delivery costs or installation costs is low, and thus the substrate size is optimum for solar cells.

Although the microwave source 900 for outputting microwaves of 915 MHz is used in each of the above embodiments, microwave sources for outputting microwaves of 896 MHz, 922 MHz, 2.45 GHz, and so on may be used. Also, the microwave source is an example of an electromagnetic wave source, and examples of the microwave source include a magnetron and a high frequency power source as long as the microwave sources output electromagnetic waves of higher than 100 MHz.

Also, a shape of the metal electrodes 310 is not limited to a square shape, and may be a triangular, hexagonal, or octagonal shape. In this case, shapes of the dielectric plates 305 and the metal covers 320 are the same as the shape of the metal electrodes 310. The metal covers 320 or the side covers may be provided or may not be provided. If there are no metal covers 320, a gas passage is formed directly in the lid 300. Also, gas emission holes may not be formed, a gas emission function may not be provided, and a lower-stage shower may be formed. The number of the metal electrodes 310 and the number of the dielectric plats 305 are not limited 8, and may be any number as long as the number is one or more.

While very appropriate embodiments of the present invention have been explained with reference to the attached drawings, of course, the present invention is not limited to the embodiments. It will be understood by one of ordinary skill in the art that various modifications or corrections can be made without departing from the scope of the present invention defined by the claims.

For example, the impedance transformation mechanism of the third coaxial waveguides 630 may be configured by combining a mechanism that non-perpendicularly extends from the second coaxial waveguide 620 and an impedance transformation mechanism formed of a dielectric such as Teflon or the like between the inner conductor 620a of the second coaxial waveguide and the inner conductor 630a of each of the third coaxial waveguides 630.

Also, in the present invention, if at least one stage of the coaxial waveguide distributor 700 includes the second coaxial waveguide 620 and 3 or more of the third coaxial waveguides 630, another transmission line may be included. Also, if each of the third coaxial waveguides 630 extends non-perpendicularly with respect to the second coaxial waveguide 620, each of the third coaxial waveguides 630 may extend in an inclined direction from the second coaxial waveguide 620, may extend while being curved, or may extend in other shapes.

A plasma processing apparatus is not limited to the aforesaid microwave plasma processing apparatus, and may be any apparatus that performs micro treatment on an object to be processed by using plasma, such as film formation, diffusion, etching, ashing, plasma doping, and the like.

Also, for example, the plasma processing apparatus according to the present invention may process a large-area glass substrate, a circular silicon wafer, or an square SOI (Silicon On Insulator) substrate.

For example, the impedance transformation mechanism of the third coaxial waveguides 630 may be configured by combining two or more among an impedance transformation mechanism of a dielectric of a capacitively coupled type described in each of the above embodiments, an impedance transformation mechanism of an impedance transformation type, and an impedance transformation mechanism of a curved-type shown as a modified example of the impedance transformation type.

1. A plasma processing apparatus for plasma processing an object to be processed by exciting a gas by using electromagnetic waves, the plasma processing apparatus comprising:
a processing container;
an electromagnetic wave source which outputs electromagnetic waves;
a transmission line which transmits the electromagnetic waves output from the electromagnetic wave source;
a plurality of dielectric plates which are disposed on an inner wall of the processing container and emit electromagnetic waves into the processing container;
a plurality of first coaxial waveguides which are adjacent to the plurality of dielectric plates and transmit electromagnetic waves to the plurality of dielectric plates; and
one stage or two or more stages of a coaxial waveguide distributor which distributes and transmits the electromagnetic waves transmitted through the transmission line to the plurality of first coaxial waveguides,
wherein at least one stage of the coaxial waveguide distributor comprises a second coaxial waveguide having an input portion and three or more of third coaxial waveguides connected to the second coaxial waveguide,
wherein each of the third coaxial waveguides has a portion that extends non-perpendicularly with respect to the second coaxial waveguide.

2. The plasma processing apparatus of claim 1, wherein each of the third coaxial waveguides has an impedance transformation mechanism.

3. The plasma processing apparatus of claim 1, wherein the number of connected portions between the second coaxial waveguide and the third coaxial waveguides in a space between the input portion of the second coaxial waveguide and an end portion of the second coaxial waveguide is two or less.

4. The plasma processing apparatus of claim 1, wherein, from among connected portions between the second coaxial waveguide and the third coaxial waveguides, an electrical length between connected portions without the input portion there between is substantially equal to an integer multiple of π rad.

5. The plasma processing apparatus of claim 4, wherein, from among connected portions between the second coaxial waveguide and the third coaxial waveguides, an electrical length between connected portions without the input portion there between is substantially equal to an integer multiple of 2π rad.

6. The plasma processing apparatus of claim 1, wherein, two of the third coaxial waveguides are connected to the second coaxial waveguide at a connected portion between the second coaxial waveguide and each of the third coaxial waveguides.

7. The plasma processing apparatus of claim 1, wherein the third coaxial waveguides are curved.

8. The plasma processing apparatus of claim 1, wherein the third coaxial waveguides are obliquely connected to the second coaxial waveguide.

9. The plasma processing apparatus of claim 1, wherein an inner conductor of each of the third coaxial waveguides is narrower than an inner conductor of the second coaxial waveguide.

10. The plasma processing apparatus of claim 1, wherein an outer conductor of each of the third coaxial waveguides is narrower than an outer conductor of the second coaxial waveguide.

11. The plasma processing apparatus of claim 1, wherein an inner conductor and an outer conductor of the second coaxial waveguide are short-circuited at least one end portion of the second coaxial waveguide,
wherein an electrical length in a space between the end portion of the second coaxial waveguide and a connected portion closest to the end portion among connected portions between the second coaxial waveguide and the third coaxial waveguides is substantially equal to an odd multiple of π/2 rad.

12. The plasma processing apparatus of claim 1, wherein, when an impedance obtained by observing a plasma side from each of the first coaxial waveguides is matched, an impedance obtained by observing the third coaxial waveguide side from a connected portion between the second coaxial waveguide and each of the third coaxial waveguides is substantially resistive,
wherein, when a resistance obtained by observing the third coaxial waveguide side from the connected portion is Rᵣ₃, the number of the third coaxial waveguides connected to a space between the input portion of the second coaxial waveguide and one end of the second coaxial waveguide is Nₛ, and a characteristic impedance of the second coaxial waveguide is Z_{c2}, the characteristic impedance Z_{c2} of the second coaxial waveguide is substantially equal to Rᵣ₃/Nₛ.

13. The plasma processing apparatus of claim 1, wherein, when a fourth coaxial waveguide having a characteristic impedance Z_{c4} is connected to the input portion of the second coaxial waveguide and an impedance obtained by observing a plasma side from each of the first coaxial waveguides is matched, an impedance obtained by observing the third coaxial waveguide side from a connected portion between the second coaxial waveguide and each of the third coaxial waveguides is substantially resistive,
wherein, when a resistance obtained by observing the third coaxial waveguide side from the connected portion is Rᵣ₃ and the number of the third coaxial waveguides connected to the second coaxial waveguide is Nₜ, the characteristic impedance Z_{c4} is substantially equal to Rᵣ₃/Nₜ.

14. The plasma processing apparatus of claim 1, wherein an electrical length of each of the third coaxial waveguides is substantially π/2 rad.

15. The plasma processing apparatus of claim 1, wherein, in an inner conductor of each of the third coaxial waveguides, a portion connected with the second coaxial waveguide is narrower than other portions.

16. The plasma processing apparatus of claim 14, wherein, when an impedance obtained by observing a plasma side from each of the first coaxial waveguides is matched, an impedance obtained by observing an output side from an output end of each of the third coaxial waveguides is substantially resistive, and when a resistance obtained by observing the output side from the output end of each of the third coaxial waveguides is Rᵣ₅, the number of the third coaxial waveguides connected to a space between the input portion of the second coaxial waveguide and one end of the second coaxial waveguide is Nₛ, and a characteristic impedance of the second coaxial waveguide is Z_{c2}, a characteristic impedance Z_{c3} of each of the third coaxial waveguides is substantially equal to (Rᵣ₅×Nₛ×Z_{c2})^{1/2}.

17. The plasma processing apparatus of claim 14, wherein, when a fourth coaxial waveguide having a characteristic impedance Z_{c4} is connected to the input portion of the second coaxial waveguide and an impedance obtained by observing a plasma side from the each of first coaxial waveguides is matched, an impedance obtained by observing an output side from an output end of each of the third coaxial waveguides is substantially resistive, and when a resistance obtained by observing the output side from the output end of each of the third coaxial waveguides is Rᵣ₅, and the number of the third coaxial waveguides connected to the second coaxial waveguide is Nₜ, a characteristic impedance Z_{c3} of each of the third coaxial waveguides is substantially equal to (Rᵣ₅×Nₜ×Z_{c4})^{1/2}.

18. The plasma processing apparatus of claim 1, wherein output end of each of the third coaxial waveguides is connected to a fifth coaxial waveguide to form T-branched shapes.

19. The plasma processing apparatus of claim 18, wherein, in at least one of an inner conductor of each of the third coaxial waveguides and an inner conductor of the fifth coaxial waveguide, the T-branched connected portion is narrower than other portions.

20. The plasma processing apparatus of claim 19, wherein, the T-branched connected portion in the inner conductor of the fifth coaxial waveguide is narrowed, and in narrowed portion of the inner conductor of the fifth coaxial waveguide, a length between the T-branched connected portion and the end of one branch is different from a length between the T-branched connected portion and the end of another branch.

21. The plasma processing apparatus of claim 18, wherein, in at least one of an outer conductor of each of the third coaxial waveguides and an outer conductor of the fifth coaxial waveguide, the T-branched connected portion is thicker than other portions.

22. The plasma processing apparatus of claim 1, further comprising a plurality of metal electrodes which are electrically connected to the inner wall of the processing container and are adjacent in a one-to-one correspondence manner to the plurality of dielectric plates,
wherein each of the dielectric plates is exposed from a space between each of the adjacent metal electrodes and the inner wall of the processing container on which each of the dielectric plates is not disposed,
wherein, each of the dielectric plates and either the inner wall of the processing container on which each of the dielectric plates is not disposed or metal covers disposed on the inner wall have substantially similar shapes or substantially symmetric shapes.

23. A plasma processing apparatus for plasma processing an object to be processed by exciting a gas by using electromagnetic waves, the plasma processing apparatus comprising:
a processing container;
an electromagnetic wave source which outputs electromagnetic waves;
a transmission line which transmits the electromagnetic waves output from the electromagnetic wave source;
a plurality of dielectric plates which are disposed on an inner wall of the processing container and emit electromagnetic waves into the processing container;
a plurality of first coaxial waveguides which are adjacent to the plurality of dielectric plates and transmit electromagnetic waves to the plurality of dielectric plates; and
one stage or two or more stages of a coaxial waveguide distributor which distributes and transmits the electromagnetic waves transmitted through the transmission line to the plurality of first coaxial waveguides,
wherein, in at least one stage of the coaxial waveguide distributor, a characteristic impedance of a coaxial waveguide at an input side and a characteristic impedance of a coaxial waveguide at an output side are different from each other.

24. The plasma processing apparatus of claim 23, wherein the coaxial waveguide at the input side is connected to the coaxial waveguide at the output side to form a two-branched shape,
wherein, in the 2-branched portion, a characteristic impedance of the coaxial waveguide at the output side is substantially two times higher than a characteristic impedance of the coaxial waveguide at the input side.

25. The plasma processing apparatus of claim 24, wherein, in an outer conductor of the coaxial waveguide at the output side constituting the 2-branched portion, the connected portion is thicker than other portions.

26. A plasma processing method comprising:
introducing a gas into a processing container;
outputting electromagnetic waves from an electromagnetic wave source;
transmitting the output electromagnetic waves to a transmission line;
distributing and transmitting the electromagnetic waves transmitted through the transmission line to a plurality of first coaxial waveguides from one stage or two or more stages of a coaxial waveguide distributor; and
emitting the electromagnetic waves transmitted through the first coaxial waveguides into the processing container from a plurality of dielectric plates that are disposed on an inner wall of the processing container,
wherein, when the electromagnetic waves are transmitted to the coaxial waveguide distributor, at least one stage of the coaxial waveguide distributor comprises a second coaxial waveguide having an input portion and three or more of third coaxial waveguides connected to the second coaxial waveguide, the electromagnetic waves are transmitted to the third coaxial waveguides each having a portion that extends non-perpendicularly with respect to the second coaxial waveguide, and the gas is excited by the electromagnetic waves emitted into the processing container through the first coaxial waveguides to plasma-process an object to be processed.

27. A plasma processing method comprising:
introducing a gas into a processing container;
outputting electromagnetic waves from an electromagnetic wave source;
transmitting the output electromagnetic waves to a transmission line;
distributing and transmitting the transmitted electromagnetic waves to a plurality of first coaxial waveguides from a coaxial waveguide distributor that is formed by one stage or two or more stages of coaxial waveguides, wherein, in at least one stage, a characteristic impedance of a coaxial waveguide at an input side and a characteristic impedance of a coaxial waveguide at an output side are different from each other;
transmitting the electromagnetic waves to a plurality of dielectric plates that are adjacent to the plurality of first coaxial waveguides and are disposed on an inner wall of the processing container;
emitting the electromagnetic waves from the plurality of dielectric plates into the processing container; and
exciting a gas by using the emitted electromagnetic waves to plasma process an object to be processed in the processing container.

28. A plasma processing apparatus for plasma processing an object to be processed by exciting a gas by using electromagnetic waves, the plasma processing apparatus comprising:
a processing container;
an electromagnetic wave source which outputs electromagnetic waves;
a transmission line which transmits the electromagnetic waves output from the electromagnetic wave source;
a plurality of dielectric plates which are disposed on an inner wall of the processing container and emit the electromagnetic waves into the processing container;
a plurality of first coaxial waveguides which are adjacent to the plurality of dielectric plates and transmit the electromagnetic waves to the plurality of dielectric plates; and
one state or two or more stages of a coaxial waveguide distributor which distributes and transmits the electromagnetic waves transmitted through the transmission line to the plurality of first coaxial waveguides,
wherein at least one stage of the coaxial waveguide distributor comprises a second coaxial waveguide having an input portion and three or more of third coaxial waveguides substantially perpendicularly connected to the second coaxial waveguide,
wherein each of the third coaxial waveguides has an impedance transformation mechanism.

29. The plasma processing apparatus of claim 28, wherein the number of connected portions between the second coaxial waveguide and the third coaxial waveguides in a space between the input portion of the second coaxial waveguide and an end portion of the second coaxial waveguide is two or less.

30. The plasma processing apparatus of claim 28, wherein, when guide wavelength of the second coaxial waveguide is λg₂, a length between connected portions between the second coaxial waveguide and the third coaxial waveguides is substantially equal to an integer multiple of λg₂/2.

31. The plasma processing apparatus of claim 30, wherein, when guide wavelength of the second coaxial waveguide is λg₂, a length between connected portions between the second coaxial waveguide and the third coaxial waveguides is substantially equal to an integer multiple of λg₂.

32. The plasma processing apparatus of claim 28, wherein, two of the third coaxial waveguides are connected to the second coaxial waveguide at a connected portion between the second coaxial waveguide and each of the third coaxial waveguides.

33. The plasma processing apparatus of claim 28, wherein an inner conductor of each of the third coaxial waveguides is narrower than an inner conductor of the second coaxial waveguide.

34. The plasma processing apparatus of claim 28, wherein an outer conductor of each of the third coaxial waveguides is narrower than an outer conductor of the second coaxial waveguide.

35. The plasma processing apparatus of claim 28, wherein an inner conductor and an outer conductor of the second coaxial waveguide are short-circuited at at least one end portion of the second coaxial waveguide,
wherein an electrical length in a space between the end portion of the second coaxial waveguide and a connected portion closest to the end portion among connected portions between the second coaxial waveguide and the third coaxial waveguides is substantially equal to an odd multiple of π/2 rad.

36. The plasma processing apparatus of claim 28, wherein, when an impedance obtained by observing a plasma side from each of the first coaxial waveguides is matched, an impedance obtained by observing the third coaxial waveguide side from a connected portion between the second coaxial waveguide and each of the third coaxial waveguides is substantially resistive,
wherein, when a resistance obtained by observing the third coaxial waveguide side from the connected portion is Rᵣ₃, the number of the third coaxial waveguides connected to a space between the input portion of the second coaxial waveguide and one end of the second coaxial waveguide is Nₛ, and a characteristic impedance of the second coaxial waveguide is Z_{c2}, the characteristic impedance Z_{c2} of the second coaxial waveguide is substantially equal to Rᵣ₃/Nₛ.

37. The plasma processing apparatus of claim 28, wherein a fourth coaxial waveguide having a characteristic impedance Z_{c4} is connected to the input portion of the second coaxial waveguide,
wherein, when an impedance obtained by observing a plasma side from each of the first coaxial waveguides is matched, an impedance obtained by observing the third coaxial waveguide side from a connected portion between the second coaxial waveguide and each of the third coaxial waveguides is substantially resistive,
wherein, when a resistance obtained by observing the third coaxial side from the connected portion is Rᵣ₃ and the number of the third coaxial waveguides connected to the second coaxial waveguide is Nₜ, the characteristic impedance Z_{c4} is substantially equal to Rᵣ₃/Nₜ.

38. The plasma processing apparatus of claim 28, wherein an electrical length of each of the third coaxial waveguides is substantially π/2 rad.

39. The plasma processing apparatus of claim 28, wherein, in an inner conductor of each of the third coaxial waveguides, a portion connected with the second coaxial waveguide is narrower than other portions.

40. The plasma processing apparatus of claim 38, wherein, when an impedance obtained by observing a plasma side from each of the first coaxial sides is matched, an impedance obtained by observing an output side from an output end of each of the third coaxial waveguides is substantially resistive, and when a resistance obtained by observing the output side from the output end of each of the third coaxial waveguides is Rᵣ₅, the number of the third coaxial waveguides connected to a space between the input portion of the second coaxial waveguide and one end of the second coaxial waveguide is Nₛ, and a characteristic impedance of the second coaxial waveguide is Z_{c2}, a characteristic impedance of each of the third coaxial waveguides is substantially equal to (Rᵣ₅×Nₛ×Z_{c2})^{1/2}.

41. The plasma processing apparatus of claim 38, wherein a fourth coaxial waveguide having a characteristic impedance Z_{c4} is connected to the input portion of the second coaxial waveguide,
wherein, when an impedance obtained by observing a plasma side from each of the first coaxial waveguides is matched, an impedance obtained by observing an output side from an output end of each of the third coaxial waveguides is substantially resistive, and when a resistance obtained by observing the output side from the output side of each of the third coaxial waveguides is Rᵣ₅ and the number of the third coaxial waveguides connected to the second coaxial waveguide is Nₜ, a characteristic impedance of each of the third coaxial waveguides is substantially equal to (Rᵣ₅×Nₜ×Z_{c4})^{1/2}.

42. The plasma processing apparatus of claim 28, wherein an impedance transformation mechanism of each of the third coaxial waveguides is a dielectric member disposed in a connected portion between an inner conductor of the second coaxial waveguide and an inner conductor of each of the third coaxial waveguides.

43. The plasma processing apparatus of claim 42, wherein, when the number of the third coaxial waveguides connected to a space between the input portion of the second coaxial waveguide and one end of the second coaxial waveguide is Nₛ, a characteristic impedance of the second coaxial waveguide is Z_{c2}, and a characteristic impedance of each of the third coaxial waveguides is Z_{c3}, a relationship Z_{c3}<Nₛ×Z_{c2} is satisfied,
wherein a reactance Xᵣ of the dielectric member is substantially equal to −(Z_{c3}(Nₛ×Z_{c2}−Z_{c3}))^{1/2},
wherein, in at least one end portion of the second coaxial waveguide, a reactance Xₚ obtained by observing the end portion side of the second coaxial waveguide from a connected portion closest to the end portion among connected portions between the second coaxial waveguide and the third coaxial waveguides is substantially equal to −Xᵣ×Z_{c2}/(Nₛ×Z_{c2}−Z_{c3}).

44. The plasma processing apparatus of claim 42, wherein a fourth coaxial waveguide having a characteristic impedance Z_{c4} is connected to the input portion of the second coaxial waveguide,
wherein, when the number of the third coaxial waveguides connected to the second coaxial waveguide is Nₜ and a characteristic impedance of each of the third coaxial waveguides is Z_{c3}, a relationship Z_{c3}<Nₜ×Z_{c4} is satisfied,
wherein a reactance Xᵣ of the dielectric member is substantially equal to −(Z_{c3}(Nₜ×Z_{c4}−Z_{c3}))^{1/2},
wherein, at both ends of the second coaxial waveguide, a reactance Xₚ obtained by observing the end portion side of the second coaxial waveguide from a connected portion closest to the end portion among connected portions between the second coaxial waveguide and the third coaxial waveguides is substantially equal to −2Xᵣ×Z_{c4}/(Nₜ×Z_{c4}−Z_{c3}).

45. The plasma processing apparatus of claim 42, wherein, an inner conductor and an outer conductor of the second coaxial waveguide are short-circuited at at least one end of the second coaxial waveguide, and in such a manner that a reactance obtained by observing the end portion side from a connected portion closest to the end portion among connected portions between the second coaxial waveguide and the third coaxial waveguides is a desired value, a distance between the end portion and the connected portion closest to the end portion is determined.

46. The plasma processing apparatus of claim 28, wherein a dielectric ring is disposed between an outer conductor and an inner conductor of the second coaxial waveguide.

47. The plasma processing apparatus of claim 28, wherein a cross-sectional shape of an outer conductor of the second coaxial waveguide is a non-circular shape.

48. The plasma processing apparatus of claim 47, wherein a cross-sectional shape of an outer conductor of the second coaxial waveguide is a half-cylindrical shape with a base upward.

49. The plasma processing apparatus of claim 28, wherein the plasma processing apparatus comprises a plurality of metal electrodes which are electrically connected to the inner wall of the processing container and are adjacent in a one-to-one correspondence manner to the plurality of dielectric plates,
wherein each of the dielectric plates is exposed from a space between each of the adjacent metal electrodes and the inner wall of the processing container on which each of the dielectric plates is not disposed,
wherein, each of the dielectric plates and either the inner wall of the processing container on which each of the dielectric plates is not disposed or metal covers disposed on the inner wall have substantially similar shapes or substantially symmetric shapes.

50. A plasma processing method comprising:
introducing a gas into a processing container;
outputting electromagnetic waves from an electromagnetic wave source;
transmitting the output electromagnetic waves to a transmission line;
distributing and transmitting the electromagnetic waves transmitted through the transmission line to a plurality of first coaxial waveguides from one stage or two or more stages of a coaxial waveguide distributor; and
emitting the electromagnetic waves transmitted through the first coaxial waveguides into the processing container from a plurality of dielectric plates that are disposed on an inner wall of the processing container,
wherein, when the electromagnetic waves are transmitted to the coaxial waveguide distributor, at least one stage of the coaxial waveguide distributor comprises a second coaxial waveguide having an input portion and 3 or more of third coaxial waveguides connected to the second coaxial waveguide, the electromagnetic waves are transmitted to the third coaxial waveguides each having an impedance transformation mechanism, and the gas is excited by the electromagnetic waves by using the electromagnetic waves emitted into the processing container through the first coaxial waveguides to plasma process an object to be processed.
